(19) United States
(12) Patent Application Publication
(10) Pub. No.: US 2026/0143860 A1
(43) Pub. Date: May 21, 2026

(54) LED DEVICE AND METHOD FOR MANUFACTURING THEREOF, LED LIGHT SOURCE COMPRISING THE SAME

(71) Applicant: Kookmin University Industry Academy Cooperation Foundation, Seoul (KR)

(72) Inventor: Young Rag DO, Seoul (KR)

(21) Appl. No.: 19/393,729

(22) Filed: Nov. 19, 2025

(30) Foreign Application Priority Data
Nov. 19, 2024 (KR) 10-2024-0165627

(51) Int. Cl. H10H 20/01; H10H 20/825; H10H 29/03; H10H 29/24

(52) U.S. Cl. CPC H10H 20/01335; H10H 20/017; H10H 20/019; H10H 20/021; H10H 20/825; H10H 29/03; H10H 29/24

(57) ABSTRACT

The present disclosure relates to a method for manufacturing an LED device. According to the present disclosure, a greater number of LED devices having a smaller chip size can be obtained from a single wafer, and each LED device produced may exhibit high-efficiency properties because dead volumes caused by surface defects generated during dry etching of the wafer and dangling bonds generated during wet etching are minimized. Accordingly, the present disclosure can be widely applied to the manufacture of light sources having high resolution and high luminance.

### CROSS-REFERENCE TO RELATED APPLICATION

The present application claims priority to Korean Application Number 10-2024-0165627, filed Nov. 19, 2024, the entire contents of which is incorporated by reference herein.

### BACKGROUND

### 1. Technical Field

The present disclosure relates to a method for manufacturing an LED device, and more particularly, to a method for manufacturing an LED device having high efficiency, an LED device manufactured thereby, and an LED light source including the LED device.

### 2. Related Art

Micro-LEDs (μLEDs) have emerged as next-generation display devices. A micro-LED display has high-performance characteristics and offers significant advantages in terms of theoretical lifetime and efficiency. However, when developing a display having 8K resolution, at least one micro-LED must be positioned on each of nearly one hundred million sub-pixels, and therefore, pick-and-place technology used for manufacturing micro-LED displays has inherent process limitations, including high cost, high defect rates, and low productivity. In addition, when producing individual micro-LEDs from a wafer, the yield of usable chips is low, and the current size of micro-LEDs is so large that only a small number of chips can be fabricated per wafer, resulting in very high manufacturing costs.

Accordingly, a method of manufacturing a micro-LED display by transferring RGB micro-LEDs onto sub-pixel positions using a laser lift-off (LLO) technique has recently been proposed.

However, in the case of the laser lift-off (LLO) technique, efficiency decreases due to laser-induced shock, making it unsuitable for use as a transfer process. In addition, this method transfers the non-uniform efficiency of the wafer as is, resulting in a display having non-uniform luminance.

To address these issues, a method has recently been proposed in which the size of micro-LEDs is reduced to 10 μm or less to implement a display, thereby greatly increasing the number of micro-LED chips obtainable from a single wafer and reducing efficiency variation between pixels. However, when manufacturing LED chips having a size of 10 μm or less, not only is there a significant problem of reduced efficiency for each chip, but the efficiency reduction becomes even more severe when implementing a display using LED chips of 10 μm or less through a laser lift-off technique due to the laser-induced shock applied during the process.

Accordingly, as an alternative, a method has recently been proposed in which a plurality of LED chips, each separated into an individual chip having a size of 10 μm or less, are implemented as a display through fluidic assembly. However, even in this alternative, the fundamental problem remains unresolved in that the external quantum efficiency significantly decreases when manufacturing micro-LEDs having a size of 10 μm or less from a wafer.

In particular, when micro-LED chips are manufactured from a wafer through dry etching, the dead volume caused by surface defects increases significantly depending on the chip size, and, for example, when the width, length, and thickness of a chip are each 92 μm, the dead volume extending inward from the surface is approximately 4.69%, whereas when the width, length, and thickness are reduced to 52 μm or 12 μm, the dead volume extending inward from the surface increases sharply to approximately 8.3% or 36%, respectively, so that, although the number of LED chips obtained from a single wafer increases, the efficiency of each LED chip is significantly reduced.

In addition, although wet etching may be considered to remove the dead volume in which surface defects have accumulated as described above, wet etching can remove only a portion of the surface defects once a large dead volume has already been generated, and, in the case of a GaN wafer fabricated in the c-plane direction, wet etching increases dangling bonds on the surface, thereby increasing surface strain and increasing nonradiative recombination, such that the detrimental effects caused by the increase in dangling bonds act relatively more strongly than the efficiency-improving effects of wet etching, resulting in the problem that the improvement in LED chip efficiency is relatively insignificant.

Accordingly, there is an urgent need for research on a method for manufacturing LED chips that are small in size yet highly efficient, capable of implementing light sources for high-resolution and high-luminance displays.

### SUMMARY

The present disclosure has been devised to solve the above-described problems, and an object of the present disclosure is to provide a method for manufacturing an LED device and an LED device manufactured thereby, in which, when obtaining a greater number of micro-LED devices from a single wafer by further reducing the chip size, the dead volume caused by surface defects generated during dry etching of the wafer is reduced so that LED devices having high efficiency can be obtained even at a small size.

In addition, another object of the present disclosure is to provide an LED light source, such as a high-resolution and high-luminance display implemented using the high-efficiency LED device having a small size according to the present disclosure, as well as an LED ink composition suitable for implementing an LED light source through various assembly processes, and a transfer LED assembly such as an interposer or a light-emitting device substrate in which LEDs are arranged at regular intervals.

In order to solve the above problems, the present disclosure provides a method for manufacturing an LED device, the method comprising separating from a wafer an LED device having a thickness of 10 μm or less and a cross-sectional area perpendicular to the thickness direction of 100 μm² or less, the method comprising: (1) forming a plurality of structures spaced apart from one another in side-surface directions by dry-etching the wafer downward in the thickness direction from an upper surface thereof according to a predefined pattern, the dry etching being performed such that an intersection angle formed between a side surface serving as an etched surface of each structure and a lower surface of the structure continuing from the wafer is 84° or less; and (2) a first recovery step of performing wet etching to remove surface defects generated on the side surfaces of the structures during the dry etching.

According to an exemplary embodiment of the present disclosure, in step (1), the dry etching may be performed such that the angle between the side surface of the structure, which is a dry-etched surface, and the bottom surface of the structure contiguous with the wafer is in a range of 60° to 84°.

In addition, in step (1), the dry etching may be performed through inductively coupled plasma-reactive ion etching (ICP-RIE) under conditions in which the etching rate is 200 nm/min or less.

In addition, the inductively coupled plasma-reactive ion etching may include a chlorine-based gas including 0-100 sccm of BCl₃ and 0-100 sccm of Cl₂ as process gases, and be performed at a process pressure of 1-100 mT.

In addition, after performing step (1) and before performing step (2), the LED structure may exhibit an average decay time measured at 300 K that is longer than an average decay time measured at 10 K.

In addition, the LED structure obtained by performing step (1) may have, according to Raman spectrum analysis, a peak-area ratio of a Ga vacancy-related defect mode located at 687 cm⁻¹ to a GaN A₁(LO) mode located at 746.62 cm⁻¹ of 15% or less.

In addition, step (2) may be performed such that an angle between a side surface of the structure subjected to the wet etching and a lower surface of the structure continuing from the wafer is 85° or greater.

In addition, the structure may include a first conductive semiconductor layer, a photoactive layer, and a second conductive semiconductor layer, each being a gallium nitride (GaN)-based semiconductor, and a Ga—O bond ratio, which is a defect among Ga—N and Ga—O bonds in a Ga 3d bonding analysis based on an XPS spectrum of a side surface of the LED structure after performing step (2), may vary by less than ±30% relative to an intrinsic Ga—O bond ratio of the wafer.

In addition, after performing step (2), the LED structure may exhibit an average decay time measured at 300 K that is longer than an average decay time measured at 10 K.

In addition, the LED structure after performing the step (2) may exhibit a longer average decay time at 300 K than the LED structure before performing the step (2).

In addition, the LED structure obtained by performing step (2) may have, according to Raman spectrum analysis, a peak-area ratio of a Ga vacancy-related defect mode located at 687 cm⁻¹ to a GaN A₁(LO) mode located at 746.62 cm⁻¹ of 8% or less.

In addition, the present disclosure may further include, after performing step (2), (3) a second recovery step in which UV is irradiated onto the LED structure.

In addition, in step (3), UV having a wavelength of 250 to 400 nm may be irradiated at an intensity of 1 mW to 100 W for 0.1 to 48 hours.

In addition, in step (3), because UV irradiation causes water molecules (H₂O) to be chemically adsorbed as —OH and —H onto the surface dangling bonds, the strain induced by the dangling bonds may be relaxed, and electrons trapped in shallow traps and deep traps may be re-trapped into the conduction band to participate again in radiative recombination, thereby increasing the emission efficiency.

In addition, after performing step (3), the LED structure may exhibit an average decay time measured at 300 K that is longer than an average decay time measured at 10 K.

In addition, the LED structure after performing the step (3) may exhibit a longer average decay time at 300 K than the LED structure before performing the step (3).

In addition, the internal quantum efficiency of the manufactured LED device may have a value of 70% to 130% relative to the internal quantum efficiency of the wafer itself.

In addition, the present disclosure provides an LED device, which has a thickness of 10 μm or less and a cross-sectional area perpendicular to the thickness direction of 100 μm² or less, the LED device being obtained by etching a wafer in the thickness direction and separating an etched structure from the wafer, wherein an average decay time measured at 300 K is equal to or longer than an average decay time measured at 10 K.

According to an exemplary embodiment of the present disclosure, the average decay time measured at 300 K may be longer than the average decay time measured at 10 K.

In addition, the average decay time measured at 300 K may be at least 15% longer than the average decay time measured at 10 K.

In addition, in luminescence measured at 300 K, the contribution of delayed luminescence originating from a shallow trap and a deep trap may be greater than the contribution of luminescence occurring at the bandgap.

In addition, in luminescence measured at 300 K, the contribution of delayed luminescence originating from a shallow trap and a deep trap may be at least twice greater than the contribution of luminescence occurring at the bandgap.

In addition, according to the Raman spectrum analysis, the peak-area ratio of the Ga vacancy-related defect mode located at 687 cm⁻¹ to the peak-area ratio of the GaN A₁(LO) mode located at 746.62 cm⁻¹ may be 8% or less, and in another example, may be 6% or less.

In addition, the LED device may include a first conductive semiconductor layer, a photoactive layer, and a second conductive semiconductor layer, each being a gallium nitride (GaN)-based semiconductor.

In addition, a Ga—O bond ratio, which is a defect among Ga—N and Ga—O bonds in a Ga 3d bonding analysis based on an XPS spectrum of a side surface of the LED device, may vary by less than ±30% relative to an intrinsic Ga—O bond ratio of the wafer.

In addition, the LED device may be manufactured by the manufacturing method according to the present disclosure.

In addition, the present disclosure provides an LED ink composition including the LED device according to the present disclosure.

In addition, the present disclosure provides a transfer LED assembly including: a transfer substrate; and a plurality of LED devices according to the present disclosure, which are arranged on the transfer substrate at predetermined intervals from one another.

In addition, the present disclosure provides an LED light source including the LED device according to the present disclosure, which is electrically connected so as to be drivable.

Hereinafter, terms used in the present disclosure will be defined.

In the description of the embodiment according to the present disclosure, when a component is described as being formed “on”, “on top of”, “under”, and “on bottom of” each layer, region, pattern, or substrate, “on”, “on top of”, “under”, and “on bottom of” include both the meanings of “directly” and “indirectly.”

Meanwhile, it is noted that the present disclosure was invented with the support of the following national research and development task.
[Assignment Unique Number] 1711199993
[Assignment Number] 00281346 (A2024-0127)
[Name of the Ministry] Korea Ministry of Science and ICT
[Name of the Assignment Managing (Professional) Organization] National Research Foundation of Korea
[Research Project Title] Nano and Materials Technology Development Project (Strategic)
[Project Name] 300 ppi High-Resolution Inorganic Light Emitting Diode with Intrinsic Stretch of 30% or More Development of Display Materials and Process Technology
[Project Implementing Organization] Hongik University Industry-Academic Cooperation Foundation
[Research Period] Aug. 1, 2023-Dec. 31, 2027
[Assignment Unique Number] 1711192466
[Assignment Number] 2021R1A2C2009521 (A2023-0130)
[Name of the Ministry] Korea Ministry of Science and ICT
[Name of the Assignment Managing (Professional) Organization] National Research Foundation of Korea
[Research Project Title] Individual Basic Research (MSIT)
[Project Name] Development of Dot-LED Materials and Display Source/Application Technology
[Project Implementing Organization] Kookmin University
[Research Period] Mar. 1, 2021-Feb. 28, 2026

The LED device manufacturing method according to the present disclosure enables a single wafer to yield LED devices of smaller chip size and in larger quantities, while minimizing the dead volume caused by surface defects generated during dry etching of the wafer and dangling bonds generated during wet etching. In addition, although the wet-etching recovery process to remove surface defects may generate dangling bonds on the device side surfaces, an additional recovery process through UV irradiation allows water molecules to be adsorbed onto the dangling bonds, thereby minimizing surface deformation of the LED devices and enabling further improved high-efficiency properties to be exhibited. Furthermore, a light source implemented using the high-efficiency LED devices of small size may have characteristics of high resolution and high luminance, and therefore is advantageous for application in various industries in which LED devices are utilized.

### BRIEF DESCRIPTION OF THE DRAWINGS

FIG. 1 is a process schematic illustrating a method for manufacturing an LED device according to an exemplary embodiment of the present disclosure.

FIG. 2A illustrates a pair of operation schematics and cross-sectional SEM images for respective steps of the LED device manufacturing method according to an exemplary embodiment of the present disclosure, wherein the left-side operation schematic and cross-sectional SEM image correspond to step (1), and the right-side operation schematic and cross-sectional SEM image correspond to step (2).

FIG. 2B illustrates a pair of operation schematics and cross-sectional SEM images for respective steps of the LED device manufacturing method according to a comparative example of the present disclosure, wherein the left-side operation schematic and cross-sectional SEM image correspond to step (1), and the right-side operation schematic and cross-sectional SEM image correspond to step (2).

FIG. 3 shows a TEM image (left), a high-resolution TEM image (center), and a diffraction-pattern photograph (right) of an LED device manufactured by performing only step (1) of the LED device manufacturing method according to an exemplary embodiment of the present disclosure.

FIG. 4 shows a TEM image (left), a high-resolution TEM image (center), and a diffraction-pattern photograph (right) of an LED device manufactured by performing only step (1) of the LED device manufacturing method according to a comparative example of the present disclosure.

FIG. 5 is a Raman spectrum of the side surface serving as the etched surface of the LED devices manufactured according to the exemplary embodiment and the comparative example of the present disclosure.

FIG. 6 is an XPS spectrum of the side surface serving as the etched surface of the LED devices manufactured according to the exemplary embodiment and the comparative example of the present disclosure.

FIG. 7 is a bar graph illustrating Ga—O, Ga—Ga, and Ga—N spectra deconvoluted from the Ga 3d bonding peak spectrum shown in FIG. 6, and quantifying the relative amounts of each of the bonds; the graph is presented in the form of a bar chart.

FIG. 8 and FIG. 9 are photoluminescence (PL) graphs measured at 300 K and 10 K, respectively, for LED devices manufactured according to the exemplary embodiment and the comparative example of the present disclosure.

FIG. 10 is a graph of internal quantum efficiency calculated from the temperature-dependent PL results of FIGS. 8 and 9. In this regard, in the tables within the drawings, “Pristine” refers to the wafer itself, “HDDE” refers to Comparative Preparation Example 1, “LDDE” refers to Preparation Example 1, “HDDE/SWE” refers to Comparative Example 1, and “LDDE/SWE” refers to Example 1.

FIG. 11 is a graph of the decay time of LED devices manufactured according to the exemplary embodiment and the comparative example of the present disclosure. In this regard, in the tables within the drawings, “Pristine” refers to the wafer itself, “HDDE” refers to Comparative Preparation Example 1, “LDDE” refers to Preparation Example 1, “HDDE/SWE” refers to Comparative Example 1, and “LDDE/SWE” refers to Example 1.

FIG. 12 is a schematic diagram illustrating the emission mechanism of recoverable low-damage dry etching (right) included in the present disclosure and limited high-damage dry etching (left) falling outside the present disclosure.

FIG. 13 and FIG. 14 are PL emission graphs measured by varying the UV irradiation time of the second recovery step when manufacturing LED devices according to the exemplary embodiment and the comparative example of the present disclosure.

FIG. 15 is a graph of internal quantum efficiency calculated using the temperature-dependent PL results of FIGS. 8 and 9 for LED devices manufactured according to the exemplary embodiment and the comparative example of the present disclosure in which UV irradiation, corresponding to the second recovery step, is performed.

FIG. 16 and FIG. 17 are graphs of the decay time of LED devices manufactured according to the exemplary embodiment and the comparative example of the present disclosure in which UV irradiation corresponding to the second recovery step is performed.

FIG. 18 is a schematic diagram illustrating the emission mechanism of delayed PL for LED devices manufactured by performing UV irradiation corresponding to the second recovery step in the LED manufacturing method according to an exemplary embodiment of the present disclosure.

FIG. 19 is a process schematic of an LED electrode assembly corresponding to an electroluminescent device used for measuring the external quantum efficiency of the obtained LED devices, and a cross-sectional SEM image of the manufactured LED electrode assembly.

FIG. 20 and FIG. 21 are graphs illustrating luminance and external quantum efficiency, respectively, measured at varying current densities through LED electrode assemblies employing LED devices manufactured according to the exemplary embodiment and the comparative example of the present disclosure in which UV irradiation corresponding to the second recovery step is performed.

### DETAILED DESCRIPTION OF THE INVENTION

Hereinafter, exemplary embodiments of the present disclosure will be described in detail so that those of ordinary skill in the art can readily implement the present invention. The present disclosure may be embodied in many different forms and is not limited to the embodiments set forth herein.

The method for manufacturing an LED device according to an exemplary embodiment of the present disclosure is a method of manufacturing an LED device having a thickness of 10 μm or less and a cross-sectional area, perpendicular to the thickness direction, of 100 μm² or less, by separating the LED device from a wafer, and may include (1) a step of dry-etching downward in the thickness direction from the upper portion of the wafer according to a predefined pattern to manufacture a plurality of structures spaced apart from one another at their side surfaces, the dry etching being performed such that an angle formed between the side surface of each structure serving as an etched surface and a lower surface of the structure adjoining the wafer is 84° or less, and (2) a first recovery step of wet-etching to remove surface defects generated on the side surfaces of the structures due to the dry etching.

First, step (1) according to the present disclosure will be described, in which a plurality of structures are manufactured by dry-etching a wafer downward in the thickness direction according to a predefined pattern.

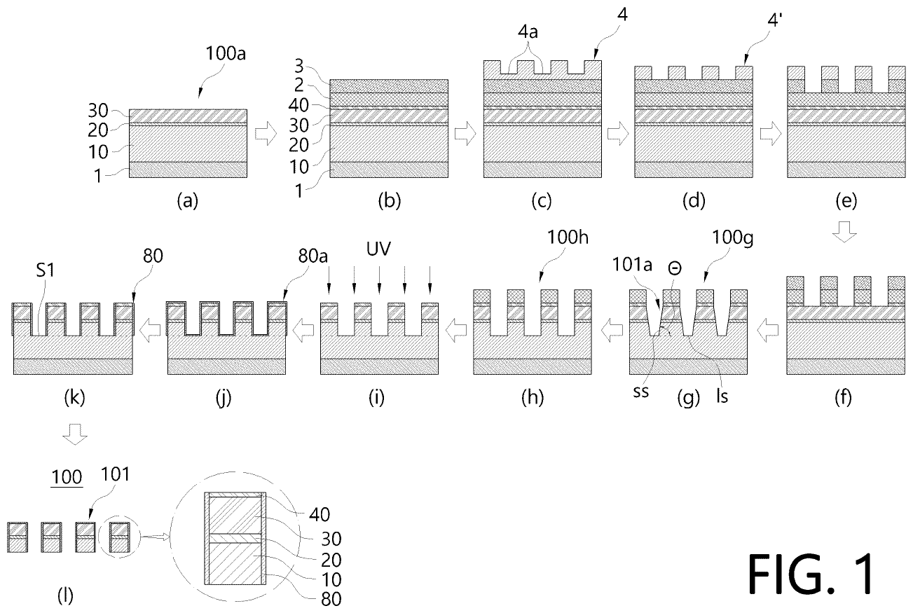

Referring to FIG. 1, the wafer 100a prepared in step (1) may be any commercially available wafer without limitation. For example, the wafer 100a may include, as a minimum configuration, a substrate 1, a first conductive semiconductor layer 10, a photoactive layer 20, and a second conductive semiconductor layer 30. In this regard, the first conductive semiconductor layer 10 may be an n-type conductive semiconductor layer, and the second conductive semiconductor layer 30 may be a p-type conductive semiconductor layer, and the n-type conductive semiconductor layer and the p-type conductive semiconductor layer may be any known conductive semiconductor layers employed in light-emitting diodes without limitation. For example, the n-type conductive semiconductor layer and the p-type conductive semiconductor layer may include III-V group semiconductors referred to as III-nitride materials, particularly binary, ternary, or quaternary alloys of gallium, aluminum, indium, and nitrogen.

Specifically, the first conductive semiconductor layer 10, which is an n-type conductive semiconductor layer, may include one or more semiconductor materials having the composition formula InₓAl_{y}Ga_{1-x-y}N (0≤x≤1, 0≤y≤1, 0≤x+y≤1), such as InAlGaN, GaN, AlGaN, InGaN, AlN, or InN, and, in a specific example, may include gallium nitride (GaN), and may be doped with a first conductive dopant (e.g., Si, Ge, Sn or the like). In addition, for example, the thickness of the first conductive semiconductor layer 10 within the wafer may be in the range of 100 nm to 20 μm.

In addition, the second conductive semiconductor layer 30, which is a p-type conductive semiconductor layer, may include one or more semiconductor materials having the composition formula InₓAl_{y}Ga_{1-x-y}N (0≤x≤1, 0≤y≤1, 0≤x+y≤1), such as InAlGaN, GaN, AlGaN, InGaN, AlN, or InN, and, in a specific example, may include gallium nitride (GaN), and may be doped with a second conductive dopant (e.g., Mg). According to a preferred embodiment of the present disclosure, the thickness of the second conductive semiconductor layer 30 may be in the range of 50 to 150 nm, but is not limited thereto.

In addition, the photoactive layer 20 positioned between the first conductive semiconductor layer 10 and the second conductive semiconductor layer 30 may be formed as a single quantum well structure or a multiple quantum well structure. The photoactive layer 20 may be any photoactive layer included in conventional LED devices used for illumination or displays, without limitation. A cladding layer (not shown) doped with a conductive dopant may be formed above and/or below the photoactive layer 20, and the cladding layer doped with the conductive dopant may be implemented as an AlGaN layer or an InAlGaN layer. In addition, materials such as AlGaN and AlInGaN may also be used as the photoactive layer 20. When an electric field is applied to the device, in such a photoactive layer (20), electrons and holes migrate from the conductive semiconductor layers respectively positioned above and below the photoactive layer to the photoactive layer, where electron-hole pair recombination occurs, thereby generating light emission. According to a preferred embodiment of the present disclosure, the thickness of the photoactive layer 20 may be in the range of 50 to 200 nm, but is not limited thereto.

Meanwhile, each layer within the wafer 100a may have a c-plane crystal structure. In addition, the wafer 100a may have undergone a cleaning process, and since the cleaning process may appropriately employ conventional cleaning solutions and cleaning procedures used for wafers, the present disclosure is not particularly limited thereto. For example, the cleaning solution may be isopropyl alcohol, acetone, or hydrochloric acid, but is not limited thereto.

Meanwhile, an electrode layer 40 may additionally be formed on the upper portion of the second conductive semiconductor layer 30 of the above-described wafer 100a (see FIG. 1(b)). The electrode layer 40 may be any electrode layer included in conventional LED devices used for illumination or displays, without limitation. The electrode layer 40 may be a single layer formed of one material selected from Cr, Ti, Al, Au, Ni, ITO, and oxides or alloys thereof, a single mixed layer formed of two or more of these materials, or a multilayer structure in which two or more of these materials form respective layers. The electrode layer 40 may be formed through a conventional method for forming an electrode layer on a semiconductor layer, and, for example, may be formed by deposition through sputtering. In addition, the electrode layer 40 may have a thickness in the range of 10 to 500 nm, but is not limited thereto. In addition, the electrode layer 40 may further undergo a rapid thermal annealing process after deposition. For example, the rapid thermal annealing process may be performed at 600° C. for 10 minutes, although the present disclosure is not particularly limited thereto, since the process conditions may be appropriately adjusted in consideration of factors such as the thickness and material of the electrode layer.

Next, the prepared wafer 100a (FIG. 1(a)) may be patterned on its upper portion according to a predefined pattern such that a plane perpendicular to the thickness direction, in which the layers are stacked in the finally implemented individual LED device 101, has a desired shape and a size of 100 μm² or less (FIGS. 1(b) to 1(f)). Specifically, assuming that the electrode layer 40 is additionally formed on the wafer 100a, a mask pattern layer may be formed on the upper surface of the electrode layer 40, and the mask pattern layer may be formed using known methods and materials employed for wafer etching, and the pattern of the mask layer may be formed by appropriately applying a conventional photolithography process, a nanoimprinting process, or the like.

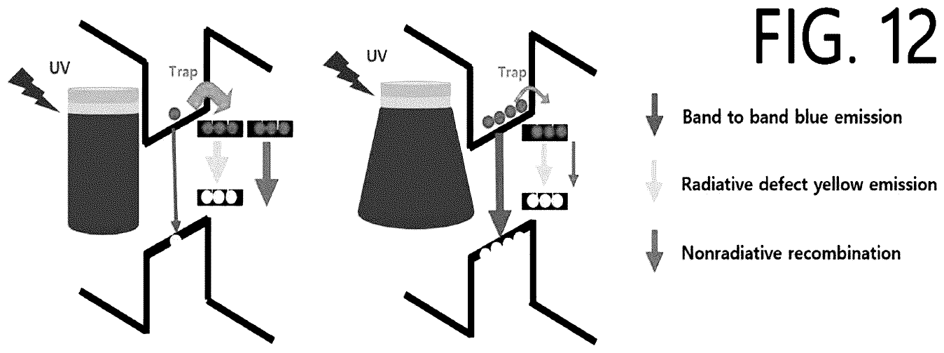

By way of example, as shown in FIG. 1(d), the mask pattern layer may be a laminate of a first mask layer 2, a second mask layer 3, and a resin pattern layer 4′, which forms a predetermined pattern on the electrode layer 40. A method of forming the mask pattern layer will be briefly described as follows. For example, the first mask layer 2 and the second mask layer 3 may be formed on the electrode layer 40 by deposition (FIG. 1(b)), and a patterned resin layer 4, from which the resin pattern layer 4′ is derived, may be formed on the second mask layer 3 (FIG. 1(c)). Thereafter, residual resin portions 4a of the resin layer 4 may be removed by a conventional method such as reactive ion etching (RIE), thereby forming the resin pattern layer 4′ (FIG. 1(d)), and then, following the pattern, the second mask layer 3, the first mask layer 2, and the electrode layer 40 may be sequentially etched (FIGS. 1(e) and 1(f)) to form the mask pattern layer. In this case, the first mask layer 2 may be formed of silicon dioxide, for example, and the second mask layer 3 may be a metal layer such as aluminum or nickel, and the etching of these layers may be performed by RIE (reactive ion etching) and ICP (inductively coupled plasma), respectively. Meanwhile, during etching of the first mask layer 2, the resin pattern layer 4′ may also be removed (see FIG. 12(f)).

Meanwhile, the patterned resin layer 4, from which the resin pattern layer 4′ is derived, may be formed by any known method such as a nanoimprinting process, photolithography using a photosensitive material, laser interference lithography, or electron-beam lithography, and the present disclosure is not particularly limited thereto.

Thereafter, as shown in FIG. 1(f), according to the predefined pattern on the second conductive semiconductor layer 30, dry etching may be performed downward in the thickness direction from the upper portion of the wafer 100a, as shown in FIG. 1(g), to obtain a wafer 100g in which a plurality of structures 101a spaced apart from one another at their side surfaces are formed. In this case, the dry etching may be performed to at least a portion of the thickness of the first conductive semiconductor layer 10 within the wafer 100a, and may be appropriately controlled in consideration of the thickness of the first conductive semiconductor layer in the LED device to be manufactured and the thickness of the first conductive semiconductor layer 10 within the wafer.

The dry etching may be performed through inductively coupled plasma-reactive ion etching (ICP-RIE), and, preferably, the ICP-RIE may be carried out under conditions in which chemical etching is dominant over physical etching. In addition, it is preferable that the dry etching be performed using inductively coupled plasma reactive ion etching (ICP-RIE) such that chemical etching is more dominant than physical etching and, after the dry etching, the angle (θ) formed between (i) the side surface (ss) of the structure 101a, which serves as the etched surface, and (ii) the lower surface (ls) of the structure that is contiguous with the wafer, is 84° or less, preferably 60° to 84°. When the structure 101a is dry-etched to have such an angle (θ), the amount of surface defects generated on the etched side surface can be reduced, and, moreover, the surface defects generated exhibit characteristics that render them recoverable in the first recovery step of step (2) described below. As a result, the recoverable portion of the surface damage can be increased, thereby enabling substantial improvement in both the internal quantum efficiency (IQE) and the external quantum efficiency (EQE) of the LED device 101 ultimately obtained.

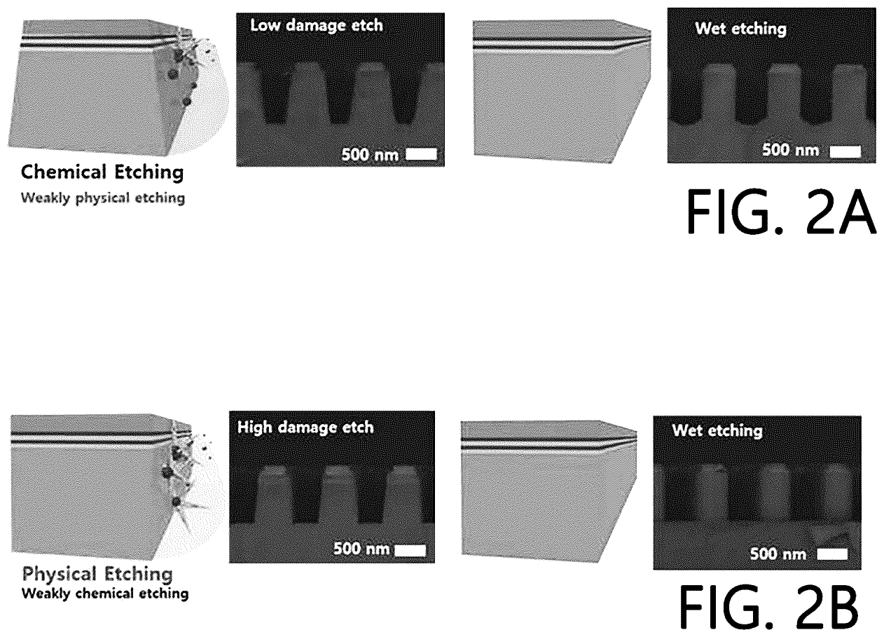

Referring to FIGS. 2A and 2B, the angle formed between the etched surface and the main surface of the wafer varies depending on whether the dry etching performed through inductively coupled plasma-reactive ion etching (ICP-RIE) is dominated by physical etching or chemical etching. Specifically, as shown in FIG. 2B, when the dry etching performed through ICP-RIE is dominated by physical etching rather than chemical etching, the etched surface may be etched at an angle of 85° or greater, nearly perpendicular (i.e., approaching) 90° to the main surface of the wafer. In contrast, as shown in FIG. 2A, when chemical etching is dominant over physical etching during ICP-RIE dry etching, the etched surface may be tapered and etched at an oblique angle, rather than being perpendicular, relative to the lower surface of the structure (or the main surface of the wafer).

Accordingly, in the manufacturing method of the present disclosure, the dry etching is performed through ICP-RIE such that chemical etching is dominant over physical etching, whereby the etched profile after the dry etching becomes tapered, and the degree to which chemical etching is dominant over physical etching is controlled such that the angle (θ) formed between the side surface (ss) of the structure 101a serving as the etched surface and the lower surface (ls) of the structure adjoining the wafer satisfies 84° or less. If, however, physical etching becomes dominant during the dry etching performed through ICP-RIE (see FIG. 2B), or, even when chemical etching is dominant, if the angle (θ) formed between the side surface (ss) of the structure 101a serving as the etched surface and the lower surface (ls) of the structure adjoining the wafer exceeds 84°, a limited (irrecoverable or low-recovery) high-damage dry etching occurs, resulting in a large dead volume, and, even if the amorphous-surface region on the dry-etched side surface (ss) of the structure 101a is removed through the first recovery step of step (2) described below, a significant amount and various types of surface defects may still remain, thereby leading to only minimal improvement in luminous efficiency.

In the following description, a dry-etching mode in which physical etching is dominant over chemical etching, specifically, a case in which the etched surface is etched at an angle of 85° or greater, or nearly perpendicular (i.e., approaching) 90° to the main surface of the wafer, is referred to as “limited high-damage dry etching” or simply “high-damage dry etching.” In addition, a dry-etching mode in which chemical etching is dominant over physical etching and in which the angle (θ) formed between the side surface (ss) of the structure 101a serving as the etched surface and the lower surface (ls) of the structure adjoining the wafer is 84° or less is referred to as “recoverable low-damage dry etching” or simply “low-damage dry etching.”

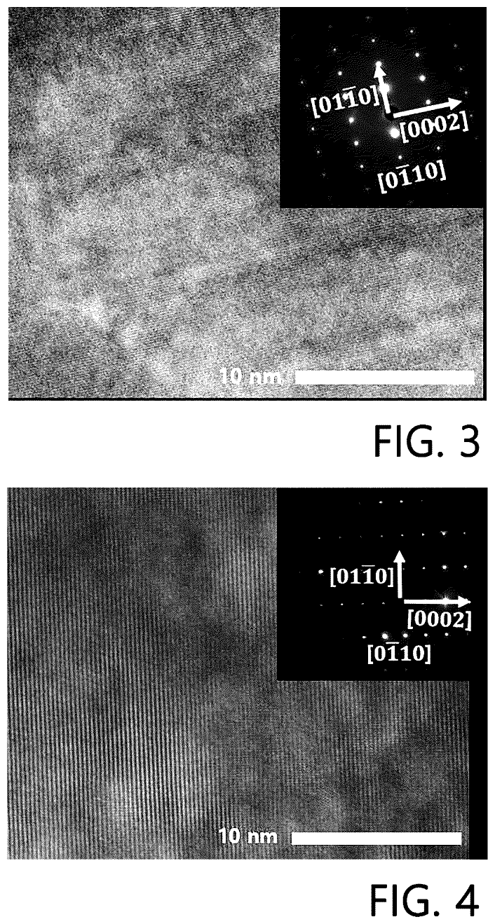

The surface defects generated by the dry etching in step (1) described above may include an amorphous region formed near the surface of the etched surface and defects caused by group-III vacancies, for example, Ga vacancies. Referring to FIGS. 3 and 4, it can be confirmed that the diffraction patterns (right-side overlaid images) of LED structures formed by limited high-damage dry etching (FIG. 4) and by recoverable low-damage dry etching (FIG. 3) each maintain their crystal structures substantially unchanged. However, when comparing the high-resolution TEM images (background images), the LED structure subjected to limited high-damage dry etching exhibits a larger dark-spot region caused by defects—that is, a larger dead volume corresponding to surface defects and internal defects—than the LED structure subjected to recoverable low-damage dry etching, from which it may be inferred that high-damage dry etching generates more surface defects than low-damage dry etching.

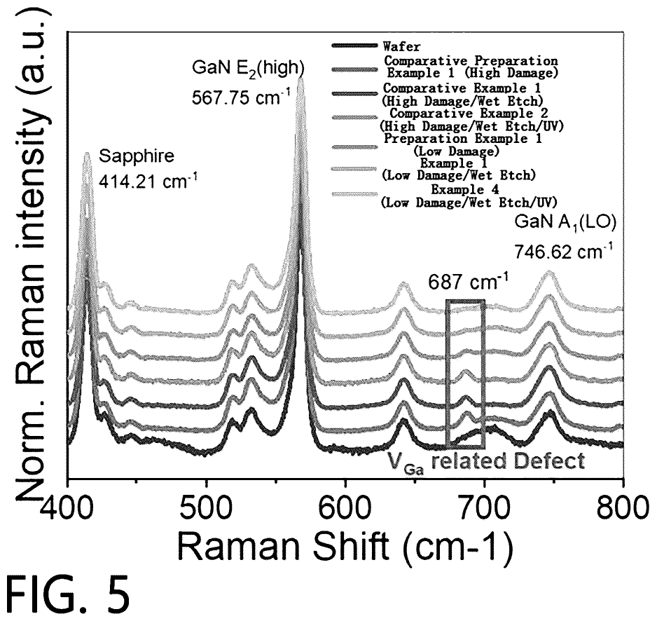

In addition, referring to FIG. 5, a defect peak attributable to Ga vacancy-related defect is observed near a wavenumber of 687 cm⁻¹ during limited high-damage dry etching, and a small amount of Ga vacancy-related defects is also observed during recoverable low-damage dry etching. From these results, it can be seen that the defects generated by the dry etching include a crystal structure with increased defects, as confirmed in FIGS. 3 and 4, and also include group-III vacancies, such as Ga vacancy-related defects. However, the amount of Group-III vacancy defect—e.g., Ga vacancy-related defects—generated differs greatly between the two etching modes, in that a large amount of Ga vacancy-related defects is generated in the limited high-damage dry etching corresponding to the conventional vertically etched dry-etching profile, whereas only a very small amount of Ga vacancy—related defects is observed in the recoverable low-damage dry etching, thereby confirming that there is a substantial difference in the overall amount of defects remaining after the dry etching.

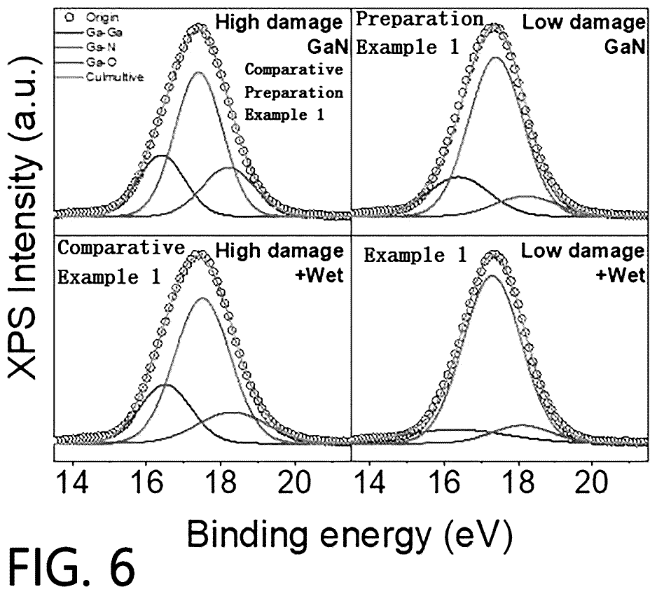

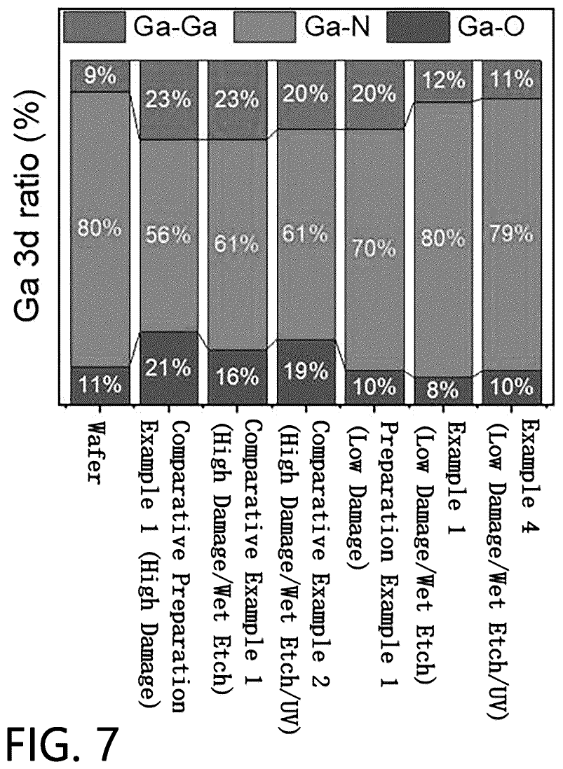

In addition, referring to FIGS. 6 and 7, when the Ga 3d peak in the XPS spectrum is measured and the spectrum is deconvoluted according to the respective bonding states, it can be confirmed that both the limited high-damage dry etching and the recoverable low-damage dry etching exhibit not only Ga—N bonds but also Ga—Ga bonds and Ga—O bonds corresponding to defects. However, when the Ga 3d peak in the XPS spectrum is measured and the spectrum is deconvoluted according to the respective bonding states and the relative amounts of each bond are quantified, it can be seen that, in the structure implemented by the limited high-damage dry etching, the Ga—O bond ratio increases by approximately 90.1% from 11% for the wafer itself after dry etching to 21%, and the Ga—Ga bond ratio likewise increases by approximately 155.5% from 9% for the wafer itself to 23%. In contrast, in the structure formed by the recoverable low-damage dry etching, the Ga—O bond ratio decreases to 10%, which is approximately a 9.1% reduction compared with 11% for the wafer itself after the dry etching, thereby confirming that, in the recoverable low-damage dry etching, the Ga—O bond either decreases relative to that of the limited high-damage dry etching or even reduces the Ga—O bond inherently present in the wafer. These results indicate that, although in both etching methods the Ga—O bond (and/or Ga—Ga bond) formed after the dry etching constitutes one of the major causes of surface defects, there is a substantial difference between the two etching methods in the total amount of defects generated, and it can be confirmed that the recoverable low-damage dry etching produces only a small amount of such defects or produces virtually none.

In addition, a notable point is that, even for the same type of defect, the degree of defect recovery achieved in the subsequent recovery process varies significantly depending on the conditions under which the dry etching has been performed. Referring to FIG. 5, in the case of the structure subjected to limited high-damage dry etching, in which a large amount of Ga vacancy-related defects is generated, the peak attributable to Ga vacancy-related defects remains almost unchanged and decreases only slightly even after the subsequent first recovery step, which is wet etching, whereas in the case of the structure subjected to recoverable low-damage dry etching, Ga vacancy-related defects are scarcely observed after the first recovery step, which is wet etching.

Meanwhile, when the Raman spectrum is analyzed for the side surface of the LED structure on which step (1), which is the recoverable low-damage dry etching, has been performed, the peak-area ratio of the Ga vacancy-related defect mode at 687 cm⁻¹ relative to the GaN A₁(LO) mode peak area at 746.62 cm⁻¹ may be 15% or less. In addition, when the Raman spectrum is analyzed for the side surface of the LED structure after performing the first recovery step (step (2)), which is wet etching, following step (1), which is the recoverable low-damage dry etching, the peak-area ratio of the Ga vacancy-related defect mode at 687 cm⁻¹ relative to the GaN A₁(LO) mode peak area at 746.62 cm⁻¹ may be 8% or less.

Specifically, referring to FIG. 5, the peak-area ratio of the Ga vacancy-related defect mode at 687 cm⁻¹ relative to the A₁(LO) mode peak area of the GaN Raman peak at 746.62 cm⁻¹ is 23.5% after the limited high-damage dry etching, whereas in the recoverable low-damage dry etching, the peak-area ratio after the dry etching is only 10.6%, confirming that the generation of Ga vacancy-related defects is significantly reduced.

Meanwhile, the fact that defect recovery is minimal even when the structure formed by the limited high-damage dry etching undergoes the first recovery step, which is wet etching, is also confirmed by the quantum-efficiency calculation.

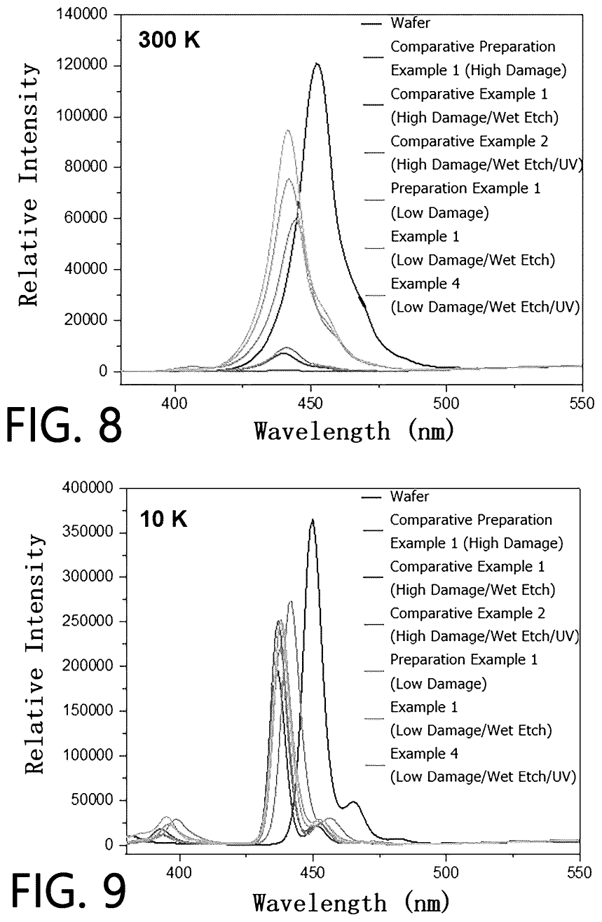

Specifically, referring to FIG. 8, at a low temperature of 10 K, the PL intensity of all samples is almost the same regardless of the etching method. This result is attributed to the fact that, as the temperature decreases, electrons excited at surface defects are not trapped, so yellow emission caused by defects and nonradiative recombination are quenched and nearly disappear, and most excitons between the conduction band and the valence band participate in radiative recombination, thereby increasing the blue emission and causing the emission intensity of most samples to become similar.

However, as shown in FIG. 9, when the PL is measured at room temperature (300 K), a large amount of surface defects is generated in the sample subjected to the limited high-damage dry etching, and, even though the amorphous structural surface region is removed by the wet etching, a substantial amount of surface defects still remains, such that, although the blue-emission intensity is recovered, the emission intensity does not increase to the desired level.

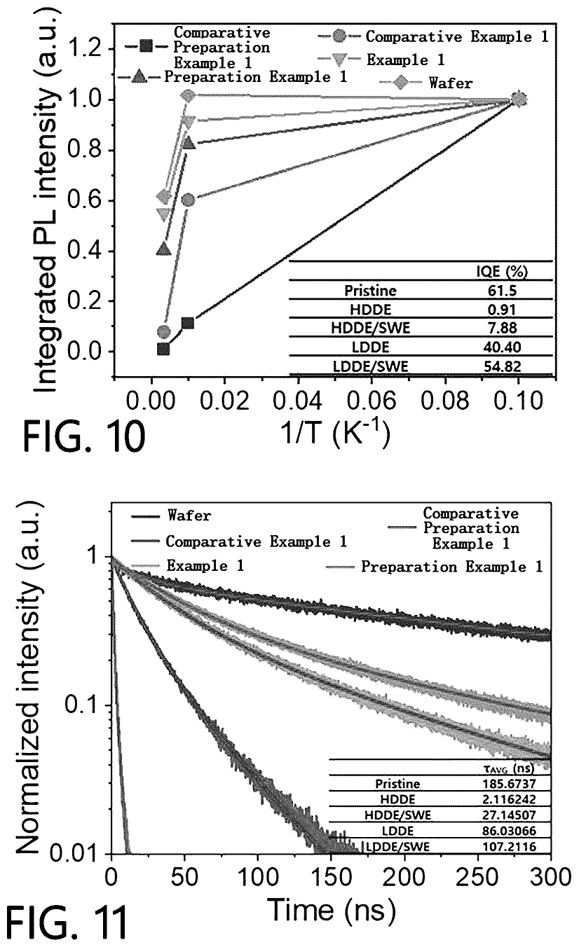

In addition, as shown in FIG. 10, the calculated internal quantum efficiency is approximately 1.48% after the limited high-damage dry etching, and, although it increases by about tenfold to reach 14.0% after the first recovery step, which is wet etching, it can be confirmed that the absolute value still remains low. In contrast, in the sample subjected to the recoverable low-damage dry etching, the internal quantum efficiency reaches 40.4% even without undergoing the first recovery step, which is wet etching, indicating that the reduction in internal quantum efficiency caused by the recoverable low-damage dry etching alone is not significant, and, after the first recovery step, which is wet etching, the internal quantum efficiency reaches 54.8%, confirming that the achieved internal quantum efficiency is extremely high—approximately 3.9 times that obtained in the case of the limited high-damage dry etching followed by wet etching.

In addition, referring to FIG. 11 to explain whether the efficiency difference of the LED devices obtained according to the etching methods described above is attributable to the characteristics of the surface defects, it can be seen that the sample subjected to the recoverable low-damage dry etching exhibits a PL decay time of 106.9 ns after the dry etching and 204.3 ns after the wet etching, showing an increase in the PL decay time after the wet etching, whereas the sample subjected to the limited high-damage dry etching exhibits a PL decay time of 3.1 ns after the dry etching and 25.4 ns after the wet etching, indicating that the decay time remains relatively very short even after the first recovery step. These results indicate that, in the case of an LED device fabricated through the limited high-damage dry etching, electrons excited by UV excitation after the dry etching are captured in the energy levels caused by surface defects and participate predominantly in non-radiative decay at the surface defect sites, with only a portion contributing to radiative decay as yellow emission, such that the decay time of the blue emission inevitably becomes very short. Accordingly, although the very short decay time of the LED device obtained through the limited high-damage dry etching may become somewhat longer by undergoing the first recovery step performed by wet etching, the result that the decay time still remains short even after the first recovery step indicates that the absolute amount of surface defects generated by the dry etching is large, and that, despite the large number of surface defects, only a very small portion of the defects can be removed, meaning that the surface defects are of a type whose recovery is limited.

In contrast, the LED device subjected to the recoverable low-damage dry etching exhibits a decay time of 106.9 ns, which is longer than that of the LED device subjected to the limited high-damage dry etching, and the decay time becomes much longer, reaching 204.3 ns, when the first recovery step is subsequently performed. Such a result indicates that the absolute amount of surface defects generated by the dry etching is small and that even these defects can mostly be removed through the recovery process, meaning that the surface defects are recoverable.

In addition, the structure produced by the recoverable low-damage dry etching may exhibit differences in average decay-time characteristics compared to the structure produced by the limited high-damage dry etching. Specifically, before the first recovery step performed by wet etching described below, the structure produced by the recoverable low-damage dry etching may have a longer average decay time measured at 300 K than the average decay time measured at 10 K. In contrast, the structure produced by the limited high-damage dry etching may have a shorter average decay time measured at 300 K than the average decay time measured at 10 K.

Accordingly, when the results of FIGS. 5 to 11 are considered together, in the case of the limited high-damage dry etching, not only is the absolute amount of defects generated large, but the defects generated exhibit only negligible recoverability or are unrecoverable, thereby producing a structure having surface defects with limited recoverability. In contrast, in the case of the recoverable low-damage dry etching, the absolute amount of defects generated is small, and the generated defects have a very high level of recoverability that can reach the defect level inherent in the wafer prior to the dry etching, thereby producing a structure having surface defects with high recoverability. In addition, it can be seen that, along with the execution of the recovery step, the manner in which the preceding dry etching is performed has a significant influence on the physical properties of the resulting LED device.

Meanwhile, referring to FIG. 12 to describe in detail the PL emission mechanism depending on the dry-etching method, in the case of the limited high-damage dry etching, even when the surface defects are reduced through the first recovery step, which is wet etching, of step (2) described later, the electrons excited by UV light are trapped in the surface defects that remain in large quantities and cannot be removed, as described above. The electrons trapped in the defects contribute partly to defect-related yellow emission and mostly to losses caused by non-radiative recombination (due to thermal IR), resulting in a reduction in the blue band-to-band emission. In contrast, in the case of the recoverable low-damage dry etching, the density of surface defects decreases significantly during the first recovery step, so that defect-related yellow emission is slightly reduced, while losses due to non-radiative recombination caused by heat or IR are greatly reduced, and the blue band-to-band emission can increase substantially.

According to an exemplary embodiment of the present disclosure, the recoverable low-damage dry etching performed through the above-described inductively coupled plasma reactive ion etching (ICP-RIE) may be carried out at an etching rate such that, after the dry etching, the angle (θ) formed between the side surface (ss) serving as the etched surface of the structure 101a and the lower surface (ls) of the structure connected to the wafer is 84° or less, and preferably 60° to 84°, as described above. For example, the etching rate may be 200 nm/min or less, more preferably 150 nm/min or less, and still more preferably in the range of 10 to 100 nm/min, whereby the amount of generated surface defects can be reduced while significantly increasing the level of recoverable surface defects. If the etching rate is less than 10 nm/min and the etching depth is large, smooth etching may be difficult to achieve, or the etching time may become excessively long. If the etching rate exceeds 200 nm/min, physical etching may become dominant, and as a result, a structure in which limited high-damage dry etching has occurred may be obtained.

In addition, the specific ICP-RIE conditions for the recoverable low-damage dry etching may vary depending on the equipment used, and, for example, the ICP power may be 50 to 350 W and the RF power may be 10 to 100 W, and more preferably, the ICP power may be 50 to 200 W and the RF power may be 10 to 100 W.

In addition, as an additional condition required for the inductively coupled plasma reactive ion etching, a chlorine-based gas including BCl₃ and Cl₂ may be used, and in this case, the flow rate of the process gas may be 0 to 100 sccm for BCl₃, or in another example 0 to 60 sccm, and 0 to 100 sccm for Cl₂, or in another example 0 to 60 sccm, which may be advantageous for achieving the objects of the present disclosure. Meanwhile, the chlorine-based gas may have a lower limit of 0 sccm or greater when both BCl₃ and Cl₂ are included, except for the case where both types have 0 sccm. In addition, the process gas may further include nitrogen gas in addition to the chlorine-based gas, and in this case, the flow rate of the nitrogen gas may be in the range of 2 to 6 sccm. Meanwhile, for example, an inert gas, such as argon gas, may not be included as a process gas. In addition, the process pressure may be in the range of 1 to 100 mT, and the DC bias voltage may be in the range of 100 to 200 V, which may be more advantageous for achieving the objects of the present disclosure. Meanwhile, it is noted that the conditions such as the ICP power, RF power, and DC bias voltage among the additional requirements for the inductively coupled plasma reactive ion etching may be adjusted depending on the specific inductively coupled plasma reactive ion etching equipment in order to achieve the same effects.

Next, in step (2) according to the present disclosure, a first recovery step of wet etching is performed to remove the surface defects on the side surfaces of the structures generated by the dry etching.

As examined in step (1), various types of surface defects are included near the surface of the etched surface during the dry etching, such as an amorphous crystal region, group-III vacancy defects such as Ga vacancies, and Ga—O and/or Ga—Ga bonds. Such surface defects significantly reduce the light emission efficiency of the resulting LED device, and as described above, even when the preferred step (1), that is, the recoverable low-damage etching, is performed, the defect level may still increase greatly compared to the inherent defect level of the wafer itself. Accordingly, in step (2) according to the present disclosure, a first recovery step of wet etching is performed on the dry-etched wafer 100g to remove the dead volume on the dry-etched structures 101a, whereby a first-recovered wafer 100h can be obtained. In addition, as shown in FIG. 3, even when the dry etching results in a tapered shape in which the etched surface is inclined and not perpendicular to the main surface of the wafer, the angle formed between the lower portion of the etched structure and the side surface serving as the etched surface can be etched to become close to a right angle through the wet etching in the subsequent step (2).

Preferably, the step (2) may be performed such that the angle formed between the side surface (ss) of the structure subjected to the wet etching and the lower surface (ls) of the structure connected to the wafer becomes 85° or greater, and any wet etching conditions capable of forming such an angle may be adopted without limitation. For example, the wet etching may be performed by immersing the structure in a wet etching solution containing an ammonium salt including a hydroxyl group or potassium at a temperature of 60 to 100° C. for 5 to 30 minutes, which may be advantageous for achieving the objects of the present disclosure.

In addition, according to an exemplary embodiment of the present disclosure, the LED structure subjected to step (2) may exhibit, in the Raman spectrum analysis performed on the side surface serving as the etched surface of the structure, a percentage of the peak area of the Ga vacancy-related defect mode at 687 cm⁻¹ relative to the GaN A₁(LO) mode peak area at 746.62 cm⁻¹ of 8% or less, thereby confirming that the surface defects are significantly reduced. Specifically, referring to FIG. 5, when the limited high-damage dry etching is followed by the first recovery step, which is wet etching, the percentage of the peak area of the Ga vacancy-related defect mode is at a level of about 11%. In contrast, it can be seen that when the recoverable dry etching is followed by the first recovery step, which is wet etching, the percentage of the peak area of the Ga vacancy-related defect mode decreases to about 4.8%, indicating that the amount of Ga vacancy-related defects remaining on the side surface of the LED device after the recovery is greatly reduced and, consequently, an LED device with excellent light emission efficiency can be obtained.

In addition, for the side surface serving as the etched surface of the LED, the Ga 3d bond analysis based on the XPS spectrum may show that the ratio of Ga—O bonds is less than ±30% relative to the Ga—O bond ratio of the wafer itself, and, in other words, in the case of the recoverable low-damage dry etching, the Ga—O bonds generated by the dry etching may be recovered through the subsequent first recovery step, which is wet etching, to the defect level inherent in the wafer before the dry etching, or rather the defects may even be improved. Referring to FIGS. 6 and 7, in the case of the recoverable low-damage dry etching, it can be seen that the ratio of Ga—O bonds, which correspond to defect-related bonds, is reduced to 9%, which is even lower than the inherent ratio of 11% of the wafer itself, thereby confirming that the defect level is improved compared to that of the wafer. In contrast, in the case of the limited high-damage dry etching, although the Ga—O bond ratio decreases from 22% after the dry etching to 16% after the first recovery step performed by wet etching, the ratio remains at 16%, which corresponds to a 45.5% increase relative to the inherent Ga—O bond ratio of 11% of the wafer. Accordingly, it can be confirmed that the resulting LED device exhibits material properties that remain significantly degraded compared to those of the wafer.

In addition, referring to FIGS. 6 and 7, the Ga—Ga bonds, which correspond to defects other than Ga—O bonds, are restored to approximately 12% after the first recovery step following the recoverable low-damage dry etching, which is slightly higher than the inherent ratio of 9% of the wafer itself, thereby confirming that the defect level is recovered to a level similar to or slightly higher than the pre-etch wafer defect level. In contrast, after the first recovery step following the limited high-damage dry etching, the Ga—Ga bond ratio reaches 23%, which is significantly higher than the inherent 9% ratio of the wafer, confirming that it is difficult to implement an LED device having a defect level comparable to that of the wafer.

Meanwhile, as described above, when the structure subjected to the recoverable low-damage dry etching in step (1) undergoes the first recovery step through step (2), a substantial portion of the defects can be removed and recovered. However, some defects may have difficulty being reduced to the level inherent to the wafer itself. In addition, due to an increase in dangling bonds, strain may be generated on the side surface serving as the etched surface.

Accordingly, according to an embodiment of the present invention, after the first recovery step of step (2), a second recovery step (FIG. 1(i)) of irradiating UV onto the wet-etched structure (100h of FIG. 1) may further be performed as step (3), and, through this, the residual defects and dangling bonds may be recovered so that the internal quantum efficiency can reach the internal quantum efficiency of the wafer itself before etching.

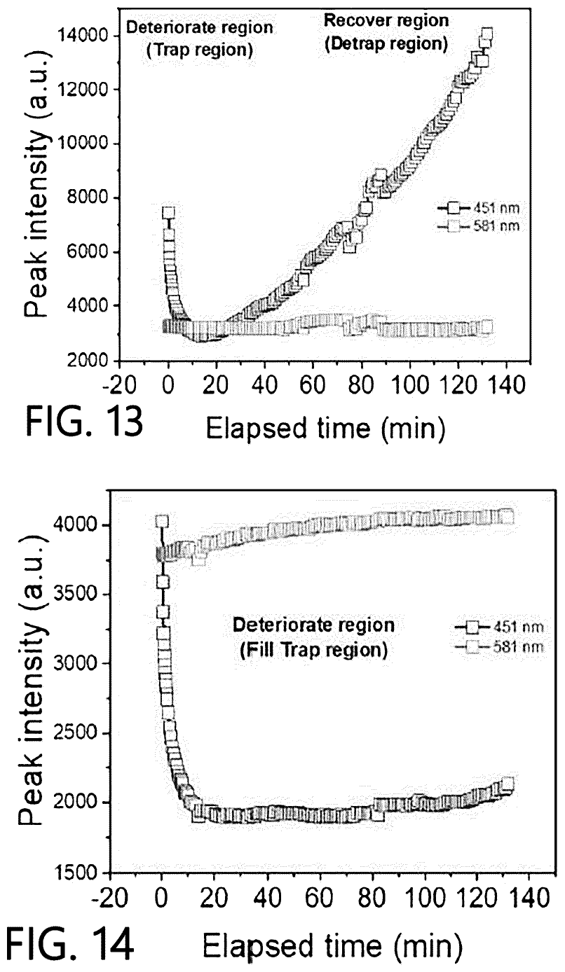

Specifically, referring to FIG. 13, it can be seen that, in the structure that has undergone the recoverable low-damage dry etching followed by the first recovery step performed by wet etching, the residual defects and dangling bonds are passivated upon UV irradiation, such that the intensity of the emission peak increases consistently with the duration of the UV irradiation. Meanwhile, the increase in the PL emission peak intensity due to the passivation of the residual defects and dangling bonds may occur over an extended period until the passivation is completed, and, for example, the passivation of the defects may reach saturation when irradiated for about 12 hours.

Meanwhile, in the second recovery step, UV irradiation does not necessarily recover the residual defects or the dangling bonds on all dry-etched surfaces under different irradiation conditions. That is, even when the structure subjected to the above-described limited high-damage dry etching undergoes the second recovery step performed by UV irradiation following the first recovery step performed by wet etching, little to no recovery of the defects may occur.

Specifically, referring to FIG. 14, it can be seen that the structure subjected to the limited high-damage dry etching followed by the first recovery step exhibits almost no change in its emission characteristics even when UV irradiation is applied. In contrast, referring to FIG. 13, it can be seen that the structure subjected to the recoverable low-damage dry etching followed by the first recovery step exhibits improved emission characteristics through the second recovery step performed by UV irradiation.

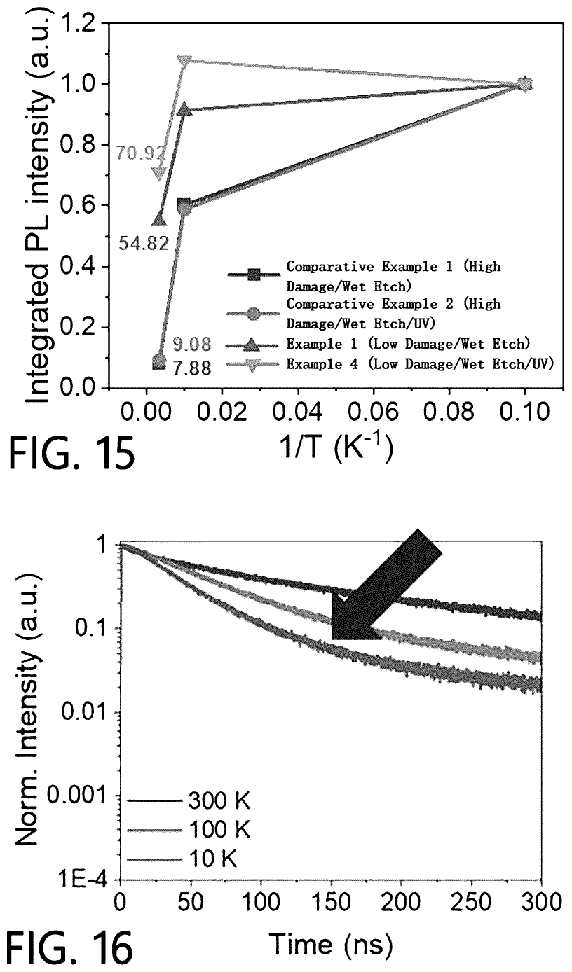

In addition, referring to FIG. 15, when the internal quantum efficiency is calculated by respectively measuring the low-temperature (10 K) PL and the room-temperature (300 K) PL of the LED device obtained after the second recovery step performed by UV irradiation, it can be seen that the LED device obtained through the limited high-damage dry etching and the wet etching exhibits an internal quantum efficiency of 15.8% after the UV irradiation, which is slightly decreased or at a similar level compared to that before the UV irradiation. In contrast, the LED device obtained through the recoverable low-damage dry etching and the wet etching exhibits an internal quantum efficiency of 71.1% after the UV irradiation, representing an improvement of about 30% from 54.8% before the UV irradiation, and it can be seen that the internal quantum efficiency can approach that of the wafer itself before the etching.

Meanwhile, in the second recovery step, the UV irradiation may induce additional defects in some of the defects that were recovered during the first recovery step, depending on the dry etching method. That is, when the limited high-damage dry etching is performed, certain defects generated during the dry etching may, even after the second recovery step, increase the level of defects that had been recovered in the first recovery step, thereby reducing the total amount of recovery achieved through the first and second recovery steps. In contrast, when the recoverable low-damage dry etching is performed, certain defects generated during the dry etching may not additionally recover the defect level that was recovered during the first recovery step through the second recovery step, but the recovered defect level can nevertheless be maintained.

Accordingly, according to an exemplary embodiment of the present disclosure, the LED structure subjected to the step (3) may satisfy that, based on the peak area of the GaN A₁(LO) mode at 746.62 cm⁻¹ in the Raman spectrum analysis performed on the side surface serving as the etched surface of the structure, the percentage of the peak area of the Ga vacancy-related defect mode at 687 cm⁻¹ remains at 8% or less, the same as that of the LED structure subjected to the step (2), and this can prevent a decrease in the extent of property improvement caused by a reduction in the total amount of recovery due to additional defect generation during the step (3).

Specifically, referring to FIG. 5, in the case of undergoing the first recovery step performed by wet etching after the limited high-damage dry etching, the percentage of the peak area of the Ga vacancy-related defect mode at 687 cm⁻¹, based on the peak area of the GaN A₁(LO) mode at 746.62 cm⁻¹ in the Raman spectrum, is 11.0%, and it is found that the defect level instead increases to 13.8% after the second recovery step performed by UV irradiation. However, in the case of undergoing the first recovery step performed by wet etching after the recoverable low-damage dry etching, the percentage of the peak area of the Ga vacancy-related defect mode at 687 cm⁻¹, based on the peak area of the GaN A₁(LO) mode at 746.62 cm⁻¹ in the Raman spectrum, is 4.8%, and it is found that the percentage remains at 4.8% even after the second recovery step performed by UV irradiation, thereby preventing a decrease in the total recovery amount.

In addition, this interpretation is also supported by the results shown in FIGS. 6 and 7. Specifically, when the Ga 3d peak in the XPS spectrum is measured and the spectrum is deconvoluted into Ga—N bonds, Ga—Ga bonds, and Ga—O bonds to quantify their relative amounts, it can be seen that, in the structure implemented by the limited high-damage dry etching, the ratio of Ga—O bonds increases by approximately 72.7% to 19% after undergoing the first recovery step and the second recovery step, compared with the Ga—O bond ratio of 11% inherent to the wafer itself, and that the Ga—Ga bond ratio also increases by approximately 133.3% from 9% inherent to the wafer itself to 21%. In contrast, in the case of the structure subjected to the recoverable low-damage dry etching, the Ga—O bond ratio shows almost no change—remaining at 11% before and after the first and second recovery steps—and therefore, when the first and second recovery steps are performed after the recoverable low-damage dry etching, it can be confirmed that the Ga—O bonds are restored to the inherent level of the wafer, as compared to the case where the first and second recovery steps are performed after the limited high-damage dry etching. This also confirms that Ga—O bonds constitute one of the principal causes of surface defects.

In addition, referring to FIG. 16, the LED device obtained through the recoverable low-damage dry etching (step (1)), the first recovery step performed by wet etching, and the second recovery step performed by UV irradiation may exhibit the same or even longer average decay time as the temperature increases, and preferably, the average decay time may become longer at higher temperatures. For example, the average decay time measured at room temperature (300 K) may be longer than the average decay time measured at low temperature (10 K), and more preferably, the average decay time measured at 300 K may be at least 30% longer than that measured at 10 K, thereby providing very high emission efficiency. In addition, the LED structure after performing the step (2) may exhibit a longer average decay time at 300 K than the LED structure before performing the step (2).

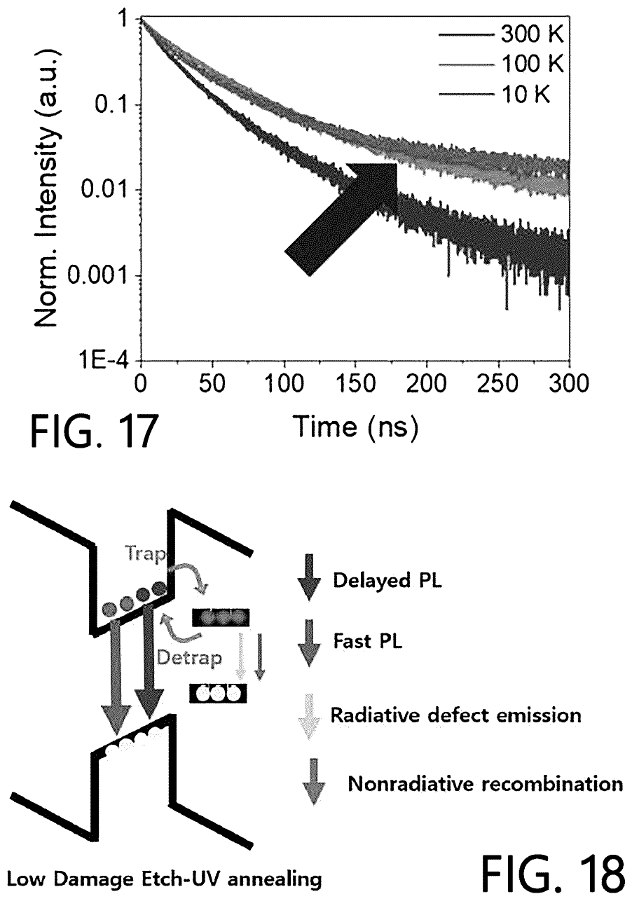

In contrast, as shown in FIG. 17, the LED device obtained through the limited high-damage dry etching, the first recovery step performed by wet etching, and the second recovery step performed by UV irradiation exhibits a decrease in the average decay time as the temperature increases from low temperature (10 K) to room temperature (300 K), despite undergoing two recovery steps. This behavior is consistent with the emission mechanism typically observed in luminescent materials containing a high density of defects.

The results shown in FIGS. 16 and 17 are attributed to a mechanism in which long-duration UV irradiation passivates the defects present on the surface, forming shallow non-quenching traps and causing delayed luminescence through multiple trapping and de-trapping processes of carriers. Although the significant reduction in defect levels is partly due to the recoverable low-damage dry etching and wet etching, the inversion of the decay time with temperature indicates that the residual defects and dangling bonds are reduced through UV passivation, thereby being converted into non-quenching traps.

Specifically, as illustrated in FIG. 18, long-duration UV irradiation passivates surface defects, thereby reducing defect-induced radiative recombination or non-radiative recombination, and de-traps electrons back into the conduction band. In this case, some electrons excited by the UV irradiation undergo rapid emission through existing electron-hole recombination, generating a peak having a short decay time. In addition, all or some of the remaining electrons excited by the UV irradiation undergo repeated trapping and de-trapping by shallow non-quenching traps and deep non-quenching traps, and some or all of the re-excited electrons returned to the conduction band then emit light slowly. As a result, a delayed-emission peak having a long decay time may coexist with the above-described peak having a short decay time, thereby ultimately producing an effect of extending the decay time. Ultimately, the phenomenon in which the average decay time becomes longer at room temperature (300 K) than at low temperature (10 K) demonstrates that the second recovery step performed through UV irradiation passivates the surface defects caused by dangling bonds into non-quenching traps, thereby enabling trapping and de-trapping to occur smoothly at room temperature.

Meanwhile, in the step (3), the UV irradiation chemically adsorbs water molecules (H₂O) onto the dangling bonds on the etched side surface as —OH and —H, thereby relieving the strain caused by the dangling bonds, and re-trapping the electrons trapped in shallow traps and deep traps back into the conduction band so that they can participate in radiative recombination, which may increase the emission efficiency.

In addition, the UV irradiated in the step (3) may have a wavelength of 250 to 400 nm and may be irradiated for 0.1 to 48 hours at an intensity of 1 mW to 100 W, which may be more advantageous for achieving the objectives of the present disclosure.

Next, the structure irradiated with UV may further undergo a step (FIG. 1(j), (k)) of forming a protective film 80 to protect the side surface from which the dead volume on the surface has been removed and in which the remaining defects have been passivated. The protective film 80 may be formed by performing a step (FIG. 1(j)) of depositing a protective-film material onto the wafer on which the UV-irradiated structure 101a is formed so as to form a protective film 80a that surrounds each exposed surface of the respective structures 101a with a predetermined thickness, and then performing a step (FIG. 1(k)) of removing the protective film deposited on the upper surface S1 of the first conductive semiconductor layer 10 between adjacent structures 101a and the protective film formed on the upper portion of the electrode layer 40 so as to expose the upper surface S1 of the first conductive semiconductor layer 10 and the electrode layer 40 to the outside. The protective-film material may include at least one selected from the group consisting of silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), lanthanum oxide (La₂O₃), scandium oxide (SC₂O₃), titanium dioxide (TiO₂), aluminum nitride (AlN), and gallium nitride (GaN). In addition, the thickness of the protective film 80 formed by depositing the protective-film material may be 5 to 100 nm, and more preferably, may be 30 to 100 nm.

Thereafter, a step of separating the plurality of structures on the wafer from the wafer may be performed.

The plurality of structures may be separated from the wafer by any known method, and the present invention is not particularly limited thereto. For example, the plurality of structures 101a may be separated from the wafer by removing a sacrificial layer or a separation layer provided in the wafer itself. Alternatively, the plurality of structures 101a may be separated by performing side etching on the lower portions of the side surfaces of the structures 101a parallel to the main surface of the wafer using wet etching, and then separating the structures using a cutting mechanism or an adhesive separation film, in accordance with Korean Laid-Open Patent Publication No. 2021-0132920 filed by the inventors of the present disclosure. Alternatively, the plurality of structures 101a may be separated from the wafer by applying a physical force such as ultrasonic energy after the side etching. Alternatively, according to Korean Laid-Open Patent Publication No. 2022-0096608 filed by the inventors of the present disclosure, the plurality of structures 101a may be separated by forming a plurality of pores, through an electrochemical method, in the upper surface S1 of the first conductive semiconductor layer 10 located between the structures 101a and in the portion of the first conductive semiconductor layer 10 extending to the lower sides of the structures 101a, immersing the wafer in a bubble-generating solution, and then applying ultrasonic energy so that the bubbles generated and grown by an ultrasonic-chemical mechanism collapse within the pores to cause pore rupture, thereby separating the plurality of structures 101a from the first conductive semiconductor layer 10 in which the plurality of pores are formed. Through this process, an LED device assembly 100 having a plurality of individually separated LED devices 101 can be obtained.

In addition, in order to separate the plurality of structures from the wafer, methods well known in the art—such as laser lift-off, chemical lift-off, or mechanical lift-off—may be employed in addition to the separation methods described above that were proposed by the inventors of the present disclosure, and the present disclosure is not particularly limited to any method for separating LED structures having an area of 100 μm² or less.

The LED device 101 obtained through the above-described manufacturing method exhibits a characteristic in which the decay time measured at 300 K is equal to, or preferably longer than, the decay time measured at 10 K. This characteristic results from the substantial removal of the defects generated on the surface during the dry etching process, while the remaining defects and dangling bonds are also passivated, thereby enabling smooth trapping and detrapping at room temperature. Accordingly, it can be indirectly demonstrated that the internal quantum efficiency of the individually implemented LED device 101 has reached a level close to the internal quantum efficiency of the wafer 101a from which the LED device 101 is derived.

In addition, in the emission measured at 300 K, the LED device 101 may exhibit delayed luminescence originating from shallow traps and deep traps that contributes more than the bandgap emission, and preferably, the contribution may be greater by a factor of two or more, thereby explaining the efficiency improvement attributable to the delayed luminescence.

The implemented LED device 101 may have a thickness of 10 μm or less, or, in another example, 0.5 to 5 μm, or 0.5 to 2.0 μm. In addition, the area of the surface perpendicular to the thickness may be 100 μm² or less, or 10 μm² or less, but is not limited thereto. Furthermore, the shape of the surface perpendicular to the thickness may be a polygon such as a triangle, a square, or a rectangle, or a closed curve such as a circle or an ellipse, and the present disclosure is not particularly limited thereto.

In addition, the thickness of the first conductive semiconductor layer 10 in the LED device 101 may be 0.5 to 9.0 μm, but is not limited thereto.

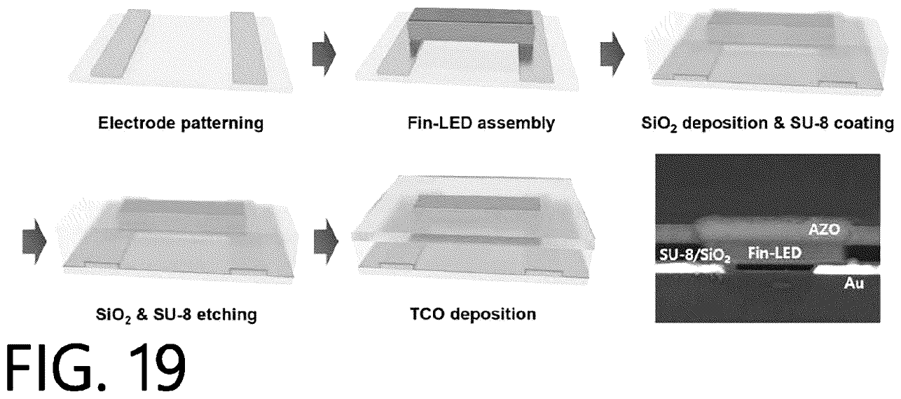

In addition, the LED device 101 implemented according to an exemplary embodiment of the present disclosure may exhibit a maximum external quantum efficiency of 5 to 20% when measured after being fabricated as an LED electrode assembly, and, as shown in FIG. 19 by way of example, it can be confirmed that the values reach 7.02% and 13.76%.

In addition, the present disclosure includes an ink composition containing the LED device 101 described above. The ink composition may further include components required in consideration of a device in which the ink composition is employed. For example, when the device is an inkjet printer, the ink composition may further include a dispersion medium and other additives provided in ink compositions for inkjet printers, and the present disclosure is not particularly limited thereto.

In addition, the present disclosure further includes an LED interposer or an LED substrate that includes a plurality of the LED devices according to the exemplary embodiment described above, in which the plurality of LED devices are arranged at uniform intervals.

The LED interposer or LED substrate may be one in which the LED devices separated by methods such as laser lift-off, chemical lift-off, or mechanical lift-off are aligned at constant intervals. In addition, since the remaining configurations and manufacturing methods other than the LED devices for implementing the LED interposer or LED substrate may appropriately adopt the configurations and manufacturing methods of known LED interposers or LED substrates, the present disclosure is not particularly limited thereto.

In addition, the present disclosure includes a light source electrically connected to the above-described LED device 101 so as to enable the LED device 101 to be driven. The light source may be, for example, various indoor or outdoor LED lighting fixtures for home or automotive use, a display, a medical device, a beauty device, various optical devices, or a component constituting any of these.

### EXAMPLES

The present disclosure will be described in further detail through the following examples; however, the following examples are not intended to limit the scope of the present disclosure and should be interpreted merely as being provided to assist in understanding the present disclosure.

### Example 1

### Preparation Example 1

A conventional LED wafer (Epistar) was prepared in which an undoped n-type group III nitride semiconductor layer, a Si-doped n-type group Ill nitride semiconductor layer (thickness: 4 μm), a photoactive layer (thickness: 0.15 μm), and a p-type group III nitride semiconductor layer (thickness: 0.05 μm) were sequentially stacked on a substrate. An electrode layer of ITO (thickness: 0.15 μm), a first mask layer of SiO₂ (thickness: 1.2 μm), and a second mask layer of Ni (thickness: 80.6 nm) were sequentially deposited on the prepared LED wafer, after which an SOG resin layer having a rectangular pattern was transferred onto the second mask layer using nanoimprint equipment. Subsequently, the SOG resin layer was cured using RIE, and the residual resin portions of the resin layer were etched by RIE to form a resin pattern layer. Thereafter, the second mask layer was etched along the pattern using ICP, and the first mask layer was etched using RIE. Thereafter, using ICP-RIE, the first electrode layer, the p-type III-nitride semiconductor layer, and the photoactive layer were dry-etched under the conditions of process gas, process pressure, ICP power, RF power, DC bias voltage, and etching rate as shown in Table 1 below, and the doped n-type III-nitride semiconductor layer was subsequently dry-etched to a thickness of 0.5 μm to form a plurality of separated structures. At this time, the angle formed between the side surface serving as the etched surface of the dry-etched structure and the lower surface of the structure was 80°.

### Preparation Example 2

A wafer on which a plurality of structures fabricated in Preparation Example 1 were formed was immersed for 13 minutes in an ammonium salt etchant containing hydroxyl groups to perform the first recovery step, which is wet etching, thereby producing a wafer on which a plurality of structures (a long side of 4 μm, a short side of 700 nm, and a height of 950 nm) with the mask pattern layer removed were formed.

### Example 2

The procedure was carried out in the same manner as in Example 1, except that the dry etching conditions using ICP-RIE were changed as shown in Table 1 below, thereby producing a wafer on which a plurality of structures were formed. According to the modified dry etching conditions, the angle formed between the side surface serving as the etched surface of the structure after the dry etching and the lower surface of the structure was 83°.

### Example 3

The procedure was carried out in the same manner as in Example 1, except that the dry etching conditions using ICP-RIE were changed as shown in Table 1 below, thereby producing a wafer on which a plurality of structures were formed. According to the modified dry etching conditions, the angle formed between the side surface serving as the etched surface of the structure after the dry etching and the lower surface of the structure was 82°.

### Comparative Example 1

### Comparative Preparation Example 1

The procedure was carried out in the same manner as Preparation Example 1 of Example 1, except that the dry etching conditions using ICP-RIE were changed as shown in Table 1 below. The angle formed between the side surface serving as the etched surface of the structure after the dry etching and the lower surface of the structure was 88°.

### Comparative Preparation Example 2

A wafer having a plurality of structures formed thereon, manufactured in Comparative Preparation Example 1, was subjected to wet etching in the same manner as in Preparation Example 2 of Example 1, thereby producing a wafer on which a plurality of structures were formed.

### Example 4

The procedure was carried out in the same manner as in Example 1, except that, after performing the dry etching and the first recovery step performed by wet etching, a second recovery step was performed by irradiating UV having a wavelength of 265 nm at an intensity of 3.3 mW for 24 hours, thereby producing a wafer on which a plurality of structures were formed.

### Comparative Example 2

The procedure was carried out in the same manner as in Comparative Example 1, except that, after performing the dry etching and the first recovery step performed by wet etching (corresponding to Preparation Examples 1-2), a second recovery step was performed by irradiating UV having a wavelength of 265 nm at an intensity of 3.3 mW for 24 hours, thereby producing a wafer on which a plurality of structures were formed.

### Preparation Example

To separate the plurality of structures from the wafer on which the plurality of structures had been prepared, the separation method disclosed in Korean Patent Laid-Open Publication No. 2022-0096608 by the present inventors was employed. Specifically, a temporary protective film made of Al₂O₃ was deposited on the wafer on which the structures were formed (with a deposition thickness of 72 nm based on the side surfaces of the structures), and thereafter, the temporary protective-film material formed between the plurality of structures was removed by RIE to expose the upper surface of the doped n-type III-nitride semiconductor layer between the structures.

Thereafter, the LED wafer having the temporary protective film formed thereon was immersed in an electrolytic solution of 0.3 M oxalic acid, the anode terminal of a power supply was connected to the wafer, and the cathode terminal was connected to a platinum electrode immersed in the electrolytic solution. A voltage of 15 V was then applied for 5 minutes to form a plurality of pores in the thickness direction from the surface of the doped n-type III-nitride semiconductor layer located between the structures. Afterward, the temporary protective film was removed by ICP, and a SiO₂ protective film was deposited to a thickness of 60 nm as measured from the side surfaces of the LED structures. Subsequently, the protective-film material formed between the LED structures was removed by RIE to expose the upper surface of the doped n-type III-nitride semiconductor layer between the structures. Then, the wafer was immersed in a bubble-generating solution of 100% gamma-butyrolactone and irradiated with ultrasound at 160 W and 40 KHz for 10 minutes, whereby the bubbles generated during the process collapsed the pores formed in the doped n-type III-nitride semiconductor layer, thus yielding multiple LED devices separated from the wafer.

TABLE 1

| | | Comparative |
|---|---|---|
| ICP-RIE Conditions | Example 1 | Example 1 |
| Process gas (flow rate, sccm) | Cl₂(10), BCl₃ (10) | Cl₂(10), BCl₃ (10) |
| Process pressure (mT) | 7.5 | 7.5 |
| ICP power (W) | 125 | 500 |
| Rf power (W) | 25 | 200 |
| DC bias voltage (V) | 170 | 660 |
| Etching rate (nm/min) | 36 | 250 |
| Angle (°) between LED | 80 | 88 |
| structure and wafer | | |
| ICP-RIE Conditions | Example 2 | Example 3 |
| Process gas (flow rate, sccm) | Cl₂(10), BCl₃ (10) | Cl₂(10), BCl₃ (10) |
| Process pressure (mT) | 7.5 | 7.5 |
| ICP power (W) | 350 | 200 |
| Rf power (W) | 100 | 50 |
| DC bias voltage (V) | 170 | 170 |
| Etching rate (nm/min) | 150 | 100 |
| Angle (°) between LED | 83 | 82 |
| structure and wafer | | |

### Experimental Example 1

The physical properties described below were measured for the wafers on which a plurality of structures were formed according to Examples 1 to 4 and 5 Comparative Examples 1 and 2.

### 1. SEM Imaging

SEM images were taken for each of the structures formed on the wafers obtained through Preparation Example 1 and Example 1, and through Comparative Preparation Example 1 and Comparative Example 1, and the results are shown in FIG. 2A (left: Preparation Example 1, right: Example 1) and FIG. 2B (left: Comparative Preparation Example 1, right: Comparative Example 1), respectively.

As can be seen from FIGS. 2A and 2B, when the physical etching becomes dominant over the chemical etching in the dry etching performed through inductively coupled plasma-reactive ion etching (ICP-RIE), the etched surface forms an angle close to 90° (88°) with respect to the main surface of the wafer, as shown in the left-side schematic and image of FIG. 2B. In contrast, when the chemical etching becomes dominant over the physical etching in the dry etching performed through ICP-RIE, the etched surface is etched in a slanted, tapering shape, as shown in the left-side schematic and image of FIG. 2A.

Meanwhile, when wet etching is performed, it can be confirmed that the etched surface forms an angle close to 90° with respect to the main surface of the wafer, as shown in the right-side schematics and images of FIGS. 2A and 2B.

### 2. TEM Imaging and Analysis

TEM images were taken of the side surface, which is the etched surface of a structure, in a wafer having a plurality of structures formed according to Preparation Example 1 of Example 1 and Preparation Example 1 of Comparative Example 1, and the results were shown in FIG. 3 (Preparation Example 1) and FIG. 4 (Comparative Preparation Example 1).

As can be seen from FIGS. 3 and 4, when observing the diffraction patterns (see the top-right photographs of each figure) of the structures etched by the limited high-damage dry etching in Comparative Preparation Example 1 and the structures etched by the recoverable low-damage dry etching in Preparation Example 1, it can be confirmed that the crystal structure remains substantially unchanged and is well maintained.

However, when observing the high-resolution TEM images, the structure in the etched state resulting from the limited high-damage dry etching of Comparative Preparation Example 1 exhibits a larger dark-spot region, i.e., dead volume, caused by defects, compared to the structure resulting from the recoverable low-damage dry etching of Preparation Example 1. Accordingly, it can be inferred that the limited high-damage dry etching generates more surface defects than the recoverable low-damage dry etching.

### 3. Raman Spectroscopy and XPS Analysis

Raman spectroscopy-based wavelength-dependent spectra were obtained for the same wafer used in Example 1 and for the wafers having multiple structures formed according to Preparation Example 1, Example 1, Example 4, Comparative Preparation Example 1, Comparative Example 1, and Comparative Example 2, and the results are shown in FIG. 5. In addition, the spectra corresponding to the Ga 3d bonding peak obtained from the XPS analysis are shown in FIG. 6. Further, based on the results of FIG. 6, the Ga—O, Ga—Ga, and Ga—N spectra were deconvoluted and the relative amounts of each were quantified using a Gaussian function, and the results are shown in FIG. 7.

As can be seen from FIG. 5, in Comparative Preparation Example 1, in which the limited high-damage dry etching was performed, a defect peak attributable to Ga vacancy is observed near a wavenumber of 687 cm⁻¹, and it can also be seen that, in Preparation Example 1, in which the recoverable low-damage dry etching was performed, Ga vacancy-related defects are likewise observed, albeit to a smaller extent.

In addition, in Comparative Example 1, which underwent the first recovery step performed by wet etching after the limited high-damage dry etching, the percentage of the peak area of the Ga vacancy-related defect mode at 687 cm⁻¹, relative to the peak area of the GaN A₁(LO) mode at 746.62 cm⁻¹, is at a level of 11%. In contrast, in the case of Example 1, which underwent the first recovery step performed by wet etching after the recoverable low-damage dry etching, the percentage of the peak area of the Ga vacancy-related defect mode is reduced to 4.8%, confirming that the amount of Ga vacancy defects inherent in the side surface of the LED device after the recovery process is significantly reduced, and that, consequently, an LED device exhibiting superior emission efficiency can be obtained.

In addition, in Comparative Example 2, which underwent the limited high-damage dry etching, the first recovery step performed by wet etching, and the second recovery step performed by UV irradiation, the defect peak attributed to Ga vacancies was observed near the wavenumber of 687 cm⁻¹. However, in Example 4, which underwent the recoverable low-damage dry etching, the first recovery step performed by wet etching, and the second recovery step performed by UV irradiation, the GA vacancy-related defects are observed only at a very small level, confirming that the defects have been substantially recovered.

In addition, as can be seen from FIGS. 6 and 7, in the structure according to Comparative Preparation Example 1 implemented by the limited high-damage dry etching, the Ga—O bond ratio increases to 21%, which is an increase of approximately 90% compared with the 11% Ga—O bond ratio of the wafer itself after the dry etching, and the Ga—Ga bond ratio likewise increases to 23% from 9% of the wafer itself, corresponding to an increase of approximately 156%. In contrast, in the structure according to Preparation Example 1 implemented by the recoverable low-damage dry etching, the Ga—O bond ratio decreases by approximately 9.1% from 11% to 10% after the dry etching, and the Ga—Ga bond ratio increases from 9% to 20%, corresponding to an increase of approximately 122%. Accordingly, compared with Comparative Preparation Example 1, it can be confirmed that the Ga—O bond decreases and the Ga—Ga bond increases to a lesser degree.

In addition, in Example 1, which underwent the first recovery step performed by wet etching after the recoverable low-damage dry etching, the Ga—O bonds generated during the dry etching were significantly reduced and were restored to 9%, which is an improvement compared with the intrinsic Ga—O bond ratio of 11% of the wafer before the dry etching. The Ga—Ga bonds were restored to 12%, which is slightly higher than the intrinsic Ga—Ga bond ratio of 9% of the wafer. However, in Comparative Example 1, which underwent the first recovery step performed by wet etching after the limited high-damage dry etching, the Ga—Ga bonds generated during the dry etching were not removed even after the first recovery step, resulting in a Ga—Ga bond ratio of 23%, which is significantly higher than the intrinsic Ga—Ga bond ratio of 9% of the wafer. In addition, in Comparative Example 1, although the Ga—O bond ratio generated during the dry etching decreased from 21% to approximately 16% through the first recovery step, it still remained higher than the intrinsic Ga—O bond ratio of 11% of the wafer, confirming that the degree of recovery is negligible compared with Example 1.

In addition, in Comparative Example 2, which underwent the limited high-damage dry etching, followed by the first recovery step performed by wet etching and the second recovery step performed by UV irradiation, the Ga—O bond ratio, even after undergoing the first and second recovery steps, was ultimately increased to 19%, corresponding to an approximately 72.7% increase compared with the intrinsic Ga—O bond ratio of 11% of the wafer. In addition, although the Ga—O bond ratio decreased from 21% to 16% after the first recovery step following the limited high-damage dry etching, the Ga—O bond ratio increased to 19% after the second recovery step, confirming that the Ga—O bonds increased rather than being further recovered through the second recovery step.

In addition, in Comparative Example 2, even after the first and second recovery steps, the Ga—Ga bond ratio also increased to 21%, which corresponds to an approximately 133.3% increase compared with the intrinsic 9% of the wafer. Since the Ga—Ga bond ratio after the first recovery step remained the same as the Ga—Ga bond ratio of 23% immediately after the dry etching, it was found that the first recovery step in Comparative Example 2 either did not recover the Ga—Ga bonds or resulted in only negligible recovery.

In contrast, in Example 4, where the structure of Preparation Example 1 produced by the recoverable low-damage dry etching underwent both the first recovery step and the second recovery step, the Ga—O bond ratio was reduced to 10%, which is lower than the intrinsic 11% of the wafer, indicating that the Ga—O bond defects were restored to the pre-dry-etch wafer level or even to an improved level. In addition, in a Ga—Ga bond-related defect, Example 4 exhibited a Ga—Ga bond ratio of 11%, which was slightly higher than the intrinsic 9% of the wafer (corresponding to an increase of approximately 22% relative to the wafer), but it can still be evaluated as having been restored to a level close to the pre-dry-etch wafer state. Furthermore, the recovery level of the Ga—Ga bond defects in Example 4 was assessed to be markedly superior compared with Comparative Example 2.

### 4. Evaluation of Temperature-Dependent PL and Internal Quantum Efficiency

Photoluminescence (PL) was measured at 300 K and 10 K for the wafer identical to that used in Example 1, as well as for the wafers having multiple structures formed according to Preparation Example 1, Example 1, Example 4, Comparative Preparation Example 1, Comparative Example 1, and Comparative Example 2, and the results are shown in FIGS. 8 and 9, respectively.

In addition, using the measured temperature-dependent PL variations, the internal quantum efficiency was calculated according to Equation 1 below, and the results are shown in FIG. 10.

$${η}_{IQE} = IPL ( 300 K ) / IPL ( 10 K ) \qquad [ Equation 1 ]$$

In Equation 1, IPL(A) denotes the integrated PL intensity measured at an absolute temperature of A K.

As can be seen from FIGS. 8 to 10, at the low temperature of 10 K in FIG. 9, the PL intensities of the examples and comparative examples exhibit nearly the same magnitude, regardless of the etching method. This is interpreted as follows: when the temperature decreases, electrons excited at surface defects are not trapped, so defect-related yellow emission and nonradiative recombination are quenched and thus nearly disappear, and excitons between the conduction band and the valence band predominantly participate in radiative recombination. As a result, the blue emission increases, and the emission intensities become similar across most samples.

However, as can be seen from FIG. 8, when the PL is measured at room temperature (300 K), in Comparative Preparation Example 1, where the limited high-damage dry etching was performed, a large number of surface defects were generated after the dry etching, and even though the amorphous surface structure was removed through wet etching (Comparative Example 1), a substantial amount of surface defects still remained, so the magnitude of the blue emission was recovered but did not increase to the desired extent. In contrast, in Examples 1 and 2, it can be confirmed that the magnitude of the blue emission was significantly restored due to the recovery of the surface defects generated during the dry etching.

Meanwhile, as can be seen from FIG. 10, the internal quantum efficiency of Comparative Preparation Example 1, which underwent the limited high-damage dry etching, was approximately 1.48%, and Comparative Example 1, which subsequently underwent the first recovery step performed by wet etching, reached an internal quantum efficiency of 14.0%. Thus, although the internal quantum efficiency of Comparative Example 1 increased by about tenfold through the first recovery step compared with Comparative Preparation Example 1, it can be confirmed that the absolute value still remained low. In contrast, in Preparation Example 1, which underwent the recoverable low-damage dry etching, the internal quantum efficiency reached 40.4% even without undergoing the first recovery step, and in Example 1, which underwent the first recovery step performed by wet etching, the internal quantum efficiency reached 54.8%. Accordingly, it can be confirmed that the recoverable low-damage dry etching alone does not significantly reduce the internal quantum efficiency, and that Example 1 exhibits an internal quantum efficiency 3.9 times higher than that of Comparative Example 1.

### 5. Evaluation of Decay Time 1

The decay time was measured using time-correlated single-photon counting (TCSPC) for the wafers on which multiple structures were formed according to the wafer used in Example 1, Preparation Example 1, Example 1, Comparative Preparation Example 1, and Comparative Example 1, and the results are shown in FIG. 11.

As can be seen from FIG. 11, the PL decay time of Preparation Example 1, which underwent the recoverable low-damage dry etching, was 106.9 ns after the dry etching, and in Example 1, which underwent the subsequent first recovery step performed by wet etching, the decay time increased to 204.3 ns.

In contrast, in Comparative Preparation Example 1, which underwent the limited high-damage dry etching, the decay time after the dry etching was 3.1 ns, and in Comparative Example 1, which underwent the subsequent first recovery step performed by wet etching, the decay time was extended to 25.4 ns; however, it is still significantly shorter compared with Preparation Example 1 and Example 1.

### 6. PL Emission Characteristics and Internal Quantum Efficiency Depending on UV Irradiation Time

For the wafers on which a plurality of structures were formed and obtained by varying the UV irradiation time in the second recovery step in Example 4 and Comparative Example 2, the PL emission was measured, and the results are shown in FIG. 13 (Example 4) and FIG. 14 (Comparative Example 2).

In addition, photoluminescence (PL) was measured at 300 K and 10 K, and using the temperature-dependent PL variation obtained from the measurements, the internal quantum efficiency was calculated through Equation 1 described above, and the results are shown in FIG. 15.

As can be seen from FIGS. 13 and 14, in Example 4, which underwent the first recovery step performed by wet etching after the recoverable low-damage dry etching and then the second recovery step performed by UV irradiation, the defects were passivated by moisture, and thus the intensity of the emission peak steadily increased as the UV irradiation time increased.

However, in Comparative Example 2, which underwent the first recovery step performed by wet etching after the limited high-damage dry etching and then the second recovery step performed by UV irradiation, it was confirmed that the emission characteristics exhibited almost no change even when the UV irradiation of the second recovery step was performed.

### 7. Evaluation of Decay Time 2

The decay time was measured for Example 4 and Comparative Example 2 in the same manner as in Experimental Example 1, and the results are shown in FIG. 16 (Example 4) and FIG. 17 (Comparative Example 2), respectively. In this case, the LED devices according to Example 4 and Comparative Example 2 were those subjected to UV irradiation for 24 hours.

As can be seen from FIGS. 16 and 17, the LED device according to Example 4, which underwent the recoverable low-damage dry etching, the first recovery step performed by wet etching, and the second recovery step performed by UV irradiation, exhibits a decay time measured at room temperature (300 K) that is longer than the decay time measured at low temperature (10 K). In contrast, the LED device according to Comparative Example 2, which was obtained after the limited high-damage dry etching, the first recovery step performed by wet etching, and the second recovery step performed by UV irradiation, exhibits a decrease in decay time as the temperature increases from low temperature (10 K) to room temperature (300 K), despite undergoing the two recovery steps. This behavior is consistent with the emission mechanism typically observed in luminescent materials containing a high density of defects.

### 8. Evaluation of External Quantum Efficiency

For the wafers having a plurality of structures formed thereon according to Example 1, Example 4, and Comparative Example 1, the plurality of structures were separated from each wafer according to the Preparation Example described above to obtain LED devices. Subsequently, for each of the obtained LED devices, an LED electrode assembly was implemented by mounting the LED device on lower electrodes spaced apart from each other on a substrate, as shown in FIG. 19, and then forming an upper electrode on the mounted LED device. In this case, the LED devices according to Example 2 were those irradiated with UV for 24 hours.

Specifically, on a quartz base substrate having a thickness of 500 μm, a lower electrode line was fabricated in which a first lower electrode and a second lower electrode, each extending in a first direction, were alternately formed so as to have a spacing of 3 μm in a second direction perpendicular to the first direction. At this time, the first lower electrode and the second lower electrode each had a width of 10 μm and a thickness of 0.2 μm, and the material of the first and second lower electrodes was gold, and the area of the region of the lower electrode line on which the LED devices were mounted was set to 1 mm². Subsequently, a solution was prepared by mixing the prepared LED devices with acetone, and 9 μL of the prepared solution was dropped twice onto the mounting region. Thereafter, an AC power source of a sine wave at 10 KHz and 40 Vpp was applied to the first lower electrode and the second lower electrode as an assembly power source, and the ultrathin fin LED devices were mounted on the lower electrodes through dielectrophoresis.

Thereafter, a first planarization was performed by depositing, to a thickness of 100 nm, a passivation material of SiO₂ by a PECVD process, and then SU-8 photoresist was coated over the region in which the LED devices were mounted to a height corresponding to the thickness of the LED devices. After etching to expose the upper surfaces of the LED devices, a plurality of upper electrodes (width of 10 μm, thickness of 0.2 μm, spacing between electrodes of 3 μm, material of TCO), extending in the second direction perpendicular to the first direction and spaced apart from one another in the first direction, were formed on the upper surfaces of the mounted LED devices to implement the LED electrode assembly.

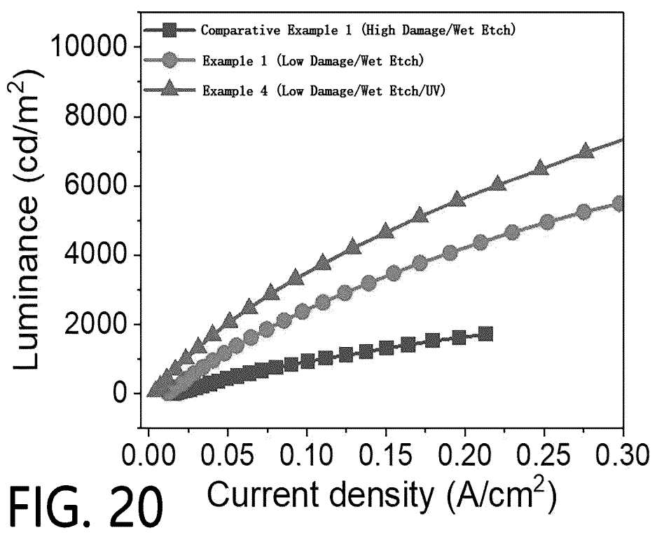

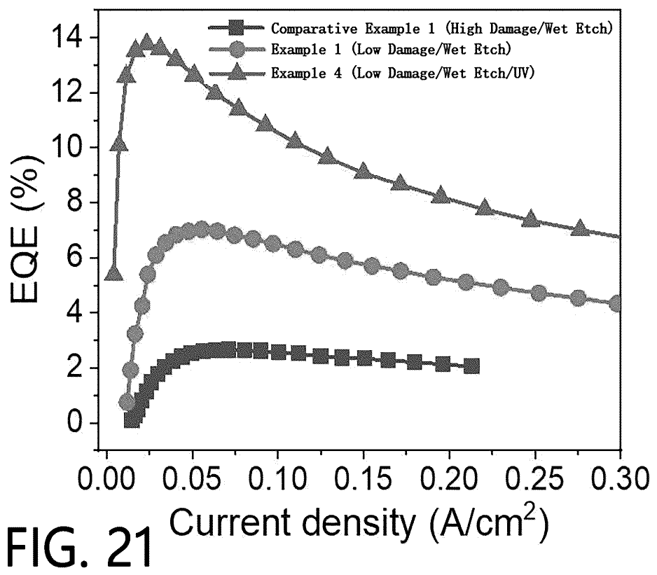

Afterward, by applying a driving power to the lower and upper electrodes of the LED electrode assembly while varying the current density and causing light emission, the luminance was measured, and the results are shown in FIG. 20. In addition, the external quantum efficiency calculated using FIGS. 8 and 9 are shown in FIG. 21.

As can be seen from FIGS. 20 and 21, the LED electrode assembly equipped with the LED devices according to Comparative Example 1 exhibited a maximum external quantum efficiency (EQE) of only 2.65%, whereas the LED electrode assembly equipped with the LED devices according to Example 1 exhibited a maximum external quantum efficiency of 7.02%, and the LED electrode assembly equipped with the LED devices according to Example 2 exhibited an external quantum efficiency of 13.76%.

In addition, the LED electrode assembly equipped with the LED devices according to Comparative Example 1 exhibited a luminance of 1024 cd/m² at 112 mA/m², depending on the current density of the applied power, whereas the LED electrode assembly equipped with the LED devices according to Example 1 exhibited a luminance of 2637 cd/m² at 110 mA/m², and the LED electrode assembly equipped with the LED devices according to Example 4 exhibited a luminance of 3747 cd/m² at 110 mA/m².

Accordingly, from these results, it can be seen that the LED device in which the defects and dangling bonds on the etched surface were recovered through Example 4 according to the present disclosure exhibits very excellent emission efficiency, and that, when an LED electrode assembly serving as an electroluminescent device is fabricated using this LED device, very high external quantum efficiency and luminance enhancement effects can be achieved.

Although exemplary embodiments of the present disclosure have been described above, the spirit of the present disclosure is not limited to the embodiments presented herein. It will be understood by those skilled in the art that various other embodiments may be readily proposed within the scope of the same inventive concept by adding, modifying, deleting, or supplementing components, and such embodiments shall also fall within the scope of the present disclosure.

What is claimed is:

1. A method for manufacturing an LED device, the method comprising separating from a wafer an LED device having a thickness of 10 μm or less and a cross-sectional area perpendicular to the thickness direction of 100 μm² or less, the method comprising:
(1) forming a plurality of structures spaced apart from one another in side-surface directions by dry-etching the wafer downward in the thickness direction from an upper surface thereof according to a predefined pattern, the dry etching being performed such that an intersection angle formed between a side surface serving as an etched surface of each structure and a lower surface of the structure continuing from the wafer is 84° or less; and
(2) a first recovery step of performing wet etching to remove surface defects generated on the side surfaces of the structures during the dry etching.

2. The method of claim 1, wherein the dry etching of step (1) is performed through inductively coupled plasma-reactive ion etching (ICP-RIE) at an etching rate of 200 nm/min or less.

3. The method of claim 2, wherein the inductively coupled plasma-reactive ion etching comprises a chlorine-based gas including 0-100 sccm of BCl₃ and 0-100 sccm of Cl₂ as process gases, and is performed at a process pressure of 1-100 m T.

4. The method of claim 1, wherein, after performing step (1) and before performing step (2), the LED structure exhibits an average decay time measured at 300 K that is longer than an average decay time measured at 10 K.

5. The method of claim 1, wherein the LED structure obtained by performing step (1) has, according to Raman spectrum analysis, a peak-area ratio of a Ga vacancy-related defect mode located near 687 cm⁻¹ to a GaN A₁(LO) mode located near 746.62 cm⁻¹ of 15% or less.

6. The method of claim 1, wherein step (2) is performed such that an intersection angle between a side surface of the structure subjected to the wet etching and a lower surface of the structure continuing from the wafer is 85° or greater.

7. The method of claim 1,
wherein the structure comprises a first conductive semiconductor layer, a photoactive layer, and a second conductive semiconductor layer, each being a gallium nitride (GaN)-based semiconductor, and
wherein a Ga—O bond ratio, which is a defect among Ga—N and Ga—O bonds in a Ga 3d bonding analysis based on an XPS spectrum of a side surface of the LED structure after performing step (2), varies by less than +30% relative to an intrinsic Ga—O bond ratio of the wafer.

8. The method of claim 1, wherein, after performing step (2), the LED structure exhibits an average decay time measured at 300 K that is longer than an average decay time measured at 10 K.

9. The method of claim 1, wherein, after performing step (2), an average decay time of the LED structure measured at 300 K is longer than an average decay time of the LED structure measured at 300 K before performing step (2).

10. The method of claim 1, further comprising:
after performing step (2),
(3) a second recovery step of irradiating UV onto the LED structure.

11. The method of claim 1, wherein the internal quantum efficiency of the manufactured LED device has a value of 70% to 130% relative to the internal quantum efficiency of the wafer.

12. An LED device, which has a thickness of 10 μm or less and a cross-sectional area perpendicular to the thickness direction of 100 μm² or less, the LED device being obtained by etching a wafer in the thickness direction and separating an etched structure from the wafer, wherein an average decay time measured at 300 K is equal to or longer than an average decay time measured at 10 K.

13. The LED device of claim 12, wherein, in luminescence measured at 300 K, the contribution of delayed luminescence originating from a shallow trap and a deep trap is greater than the contribution of luminescence occurring at the bandgap.

14. The LED device of claim 13, wherein, in luminescence measured at 300 K, the contribution of delayed luminescence originating from a shallow trap and a deep trap is at least twice greater than the contribution of luminescence occurring at the bandgap.

15. The LED device of claim 12, wherein an average decay time measured at 300 K is at least 15% longer than an average decay time measured at 10 K.

16. The LED device of claim 12,
comprising a first conductive semiconductor layer, a photoactive layer, and a second conductive semiconductor layer, each being a gallium nitride (GaN)-based semiconductor,
wherein a Ga—O bond ratio, which is a defect among Ga—N and Ga—O bonds in a Ga 3d bonding analysis based on an XPS spectrum of a side surface of the LED device, varies by less than ±30% relative to an intrinsic Ga—O bond ratio of the wafer.

17. The LED device of claim 12, wherein, based on Raman spectrum analysis, a peak-area ratio of a Ga vacancy-related defect mode located near 687 cm⁻¹ to a GaN A₁(LO) mode peak area located near 746.62 cm⁻¹ is 8% or less.

18. The LED device of claim 12, wherein dangling bonds on a side surface of the LED device are adsorbed with water molecules.

19. A transfer LED assembly, comprising:
a transfer substrate; and
a plurality of LED devices according to claim 12, arranged on the transfer substrate at predetermined intervals with respect to one another.

20. An LED light source comprising a plurality of LED devices according to claim 12, the plurality of LED devices being electrically connected so as to be drivable.
